(19) United States
(12) Patent Application Publication
(10) Pub. No.: US 2025/0275226 A1
(43) Pub. Date: Aug. 28, 2025

(54) SILICON CARBIDE DEVICES

(71) Applicant: The Government of the United States of America, as represented by the Secretary of the Navy, Arlington, VA (US)

(72) Inventor: Francis J. Kub, Arnold, MD (US)

(21) Appl. No.: 19/065,878

(22) Filed: Feb. 27, 2025

Related U.S. Application Data
(60) Provisional application No. 63/558,269, filed on Feb. 27, 2024.

(51) Int. Cl. H10D 84/00; H10D 8/60; H10D 30/66; H10D 62/00; H10D 62/10; H10D 62/60; H10D 62/832; H10D 62/834

(52) U.S. Cl. CPC H10D 84/146; H10D 8/60; H10D 30/668; H10D 62/056; H10D 62/102; H10D 62/124; H10D 62/60; H10D 62/8325; H10D 62/834

(57) ABSTRACT

Described herein are semiconductor devices that include an epitaxial silicon carbide drift region with vertical current transport having a rectifying current injector or field effect transistor current injector on the upper portion of the drift layer and a lower portion having a contact on a substrate or contact on a drift layer to collect current.

### CROSS-REFERENCE TO RELATED APPLICATIONS

This patent application claims priority to U.S. Provisional Patent Application Ser. No. 63/558,269, filed Feb. 27, 2024; which is incorporated by reference herein in its entirety into this disclosure.

### FEDERALLY-SPONSORED RESEARCH AND DEVELOPMENT

The United States Government has ownership rights in this subject disclosure. Licensing inquiries may be directed to Office of Technology Transfer, US Naval Research Laboratory, Code 1004, Washington, DC 20375, USA; +1.202.767.7230; techtran@nrl.navy.mil, referencing NC 212526.

### BACKGROUND OF THE SUBJECT DISCLOSURE

### Field of the Subject Disclosure

The present subject disclosure relates generally to semiconductor devices. More particularly, the present subject disclosure relates to silicon carbide devices.

### Background of the Subject Disclosure

Superjunction-type drift regions have been introduced in which the drift region is divided into alternating, side-by-side heavily doped n-type and p-type regions. In vertical semiconductor devices, these side-by-side n-type and p-type regions are often referred to as “pillars.” The pillars may have fin shapes, column shapes or other shapes. The thickness and doping of these pillars may be controlled so that the superjunction will act like a p-n junction with low resistance and a high breakdown voltage. Thus, by using superjunction structures, the conventional tradeoff between the breakdown voltage of the device and the doping level of the drift region may be avoided. Typically, at least some of the pillars are formed via ion implantation, and so-called “deep” implantation is used to enhance the effect of the superjunction structure.

In superjunction devices, the doping concentration in the drift region may be increased in order to reduce the on-state resistance of the device with reduced effect on the breakdown voltage. Because of this superjunction structure, the top portion of the drift region (i.e., the n-type spreading layer) can be doped more heavily than would otherwise be possible for a conventional structure. This enables the device to have lower on-state resistance than would otherwise be possible for a given pillar voltage.

A multi-step channeling implant may be used for the formation of deep ion implanted p-type pillars and n-type pillars. This doping profile may facilitate forming a generally charge-balanced superjunction structure deep within the drift region that may reduce the on-resistance of the Junction Barrier Schottky (JBS) diode (or other device), and which may reduce the electric field intensity at the Schottky junction, allowing for use of a lower Schottky barrier height Schottky contact.

The channeled implant allows the formation of a deep junction with a relatively flat doping profile. The channeled ion implantation may be performed at room temperature, which may reduce manufacturing costs. Additionally, the channeled implant may result in significantly less damage to the silicon carbide crystal, as the ions penetrate deep into the crystal with greatly reduced scattering (which causes crystal damage), and the ions arc primarily slowed and stopped within the crystal lattice due to electron cloud interactions. The angle of implantation with respect to the top surface of the 4H silicon carbide layer structure will depend upon how the 4H silicon carbide wafer that forms the substrate is cut from the boule.

An approach for forming superjunction structures in 4H silicon carbide has recently been proposed, as disclosed in U.S. Patent Publication No. 2015/0028350, which is incorporated by reference herein in its entirety into this disclosure. Under this approach, the n-type and p-type pillars are formed via ion implantation, where the ion implantation is carefully controlled to be at an implant angle of less than 2° from the <0001> crystallographic axis so that the ions may channel into the crystal. This approach has been shown to yield junction depths of up to 4 microns with 900 keV implant energies. In addition, the ion implantation may be performed along the <11-20> crystallographic axis, which exhibits very large channels along with a low surface density of atoms as viewed along the axis of implantation. It has been demonstrated that far deeper ion implantations can be achieved (for a given ion implantation energy) by performing the ion implantation along such channels in the lattice structure, which can be used to provide lower cost and/or higher performing power semiconductor devices.

Aluminum ion implanted regions are typically used in P-Well and P-type regions of silicon carbide MOSFET and silicon carbide superjunction MOSFETs. Aluminum ion implanted regions are typically used because aluminum has a low diffusion coefficient in silicon carbide. It is desirable to use aluminum because the lateral diffusion of the P-type dopant can narrow the JFET region of a SiC MOSFET or the N-type column for conducting electrons in SiC superjunction MOSFET.

A need exists for improved silicon carbide superjunction and UMOSFET devices.

### SUMMARY OF THE SUBJECT DISCLOSURE

In some embodiments, the objective of this subject disclosure is to describe a structure and method for a superjunction device that utilizes a combination of aluminum and boron ion implantation to achieve a deep ion implanted p-type pillar. The boron region of the p-type pillar can be a low diffusion p-type pillar. Channeling ion implantation can be used for the region of the p-type pillar formed using aluminum ion implantation. Channeling ion implantation can be used for the region of the p-type pillar using boron ion implantation. The channeling ion implantation approach can be used to form deep ion implanted p-type pillar. Channeling ion implantation can be used to form deep n-type ion implanted n-type pillars.

In some embodiments, the low diffusion boron p-type pillar beneath a p-type well can reduce the electric field in the gate insulator beneath a gate electrode for UMOSFET and COOLMOSFET transistor providing a higher unit cell density and higher current performance device. The low diffusion boron region beneath the p-type well can be formed by ion implantation. The energy of the ion implanter that is used to ion implant the boron atoms or compounds containing boron atoms can be in the range of 100 keV to 15 keV. The ion implantation can optionally be performed using channelling to achieve a deeper low boron diffusion P-type pillar beneath the p-type well. A multistep ion implantation can be performed in forming the low diffusion P-type pillar. The SiC UMOSFET and COOLMOSFET have a n-type JFET region between the P-type wells and may be formed by n-type ion implantation. The p-type wells may be formed by aluminum ion implantation. The p-type wells may also be formed by low diffusion boron. The edge of the diffusion p-type pillar near the n-type JFET region may be coincident with the edge of the p-type well near the n-type JFET region or may be offset from the edge of the p-well by a lateral separation in the range of zero microns to 3 microns. The SiC UMOSFET or COOLMOSFET devices may or may not include quasi-charge balance structures. Other embodiments may or may not include quasi-charge balance structures. This embodiment has significant benefit over current SiC UMOSFET and COOLMOSFET devices.

Described herein are various semiconductor devices with unique and improved features over conventional devices.

In an exemplary embodiment, the present subject disclosure is a semiconductor device. The device includes a drift region having an upper portion and a lower portion with a first conductivity type in the lower portion; and a plurality of implanted regions containing boron and having a second conductivity type in the upper portion of the drift region, wherein the low boron diffusion is formed so that the boron diffusion in the implanted regions is limited; wherein the lower portion of the implanted regions form a superjunction structure in the drift region

In another exemplary embodiment, the present subject disclosure is a semiconductor device. The device includes a drift region having a first n-type conductivity, type; and a plurality of boron P-type implanted regions having a P-type conductivity type in an upper portion of the drift region, wherein the first n-type conductivity type dopant density overcompensates boron dopant that diffuses into the first n-type conductivity type; and wherein the lower portions of the implanted regions form a superjunction structure in the drift region

### BRIEF DESCRIPTION OF THE DRAWINGS

The patent or application file may contain at least one drawing executed in color. Copies of this patent or patent application publication with color drawing(s) will be provided by the Office upon request and payment of the necessary fee.

The accompanying drawings, which are included to provide a further understanding of the subject disclosure and are incorporated in and constitute a part of this application, illustrate certain embodiment(s) of the subject disclosure.

In the drawings:

FIG. 1 is a schematic cross-sectional diagram of a conventional power semiconductor device that has a superjunction-type drift region, according to an exemplary embodiment of the present subject disclosure.

FIG. 2 is a schematic of a superjunction SiC DMOSFET with composite P-type pillar, according to an exemplary embodiment of the present subject disclosure.

FIG. 3 is a schematic of a superjunction SiC UMOSFET with composite P-type pillar and an optional low diffusion P-type pillar, according to an exemplary embodiment of the present subject disclosure.

FIG. 4 is a schematic of a superjunction SiC COOLMOSFET with composite P-type pillar and optional low diffusion P-type pillar, according to an exemplary embodiment of the present subject disclosure.

FIG. 5 is a schematic of a superjunction SiC device with composite P-type pillar and optional low diffusion P-type pillar, according to an exemplary embodiment of the present subject disclosure.

FIG. 6 is a schematic cross-sectional diagram of a conventional power semiconductor device that has a superjunction-type drift region with low diffusion P-type pillar, according to an exemplary embodiment of the present subject disclosure.

FIG. 7 is a schematic of a superjunction SiC DMOSFET with low diffusion P-type pillar, according to an exemplary embodiment of the present subject disclosure.

FIG. 8 is a schematic of a superjunction SiC UMOSFET with low diffusion P-type pillar, according to an exemplary embodiment of the present subject disclosure.

FIG. 9 is a schematic of a superjunction SiC COOLMOSFET with low diffusion P-type pillar, according to an exemplary embodiment of the present subject disclosure.

FIG. 10 is a schematic of a superjunction SiC device with low diffusion P-type pillar, according to an exemplary embodiment of the present subject disclosure.

FIG. 11 is a schematic of a retrograde multi-step ion implant dopant profile, according to an exemplary embodiment of the present subject disclosure.

FIG. 12A shows a silicon carbide superjunction power switch.

FIG. 12B shows silicon carbide superjunction devices have been fabricated using an aluminum implant.

FIG. 13A shows an ion implanted and anneal SiC shows large boron diffusion tail 720 and deep diffusion.

FIG. 13B shows co-implantation of carbon and boron shows large reduction in the boron diffusion tail and also can allow complete stoppage of boron diffusion.

FIG. 14 shows diffusivity levels of carbon, silicon, and boron.

FIG. 15A shows a Boron ion implanted region. Utilize carbon+boron ion implantation or unmasked carbon ion implantation to reduce carbon vacancies to reduce lateral diffusion of boron into the N-type conduction channel 752.

FIG. 15B shows Commercial High Energy Ion Implanters.

FIG. 16 shows another exemplary embodiment of present subject disclosure depicted as a Composite pillar structure of aluminum and boron.

FIGS. 17A, 17B, and 17C show state of the art for Rohm UMOSFET as dummy trench structures on the sides of UMOSFET to reduce electric field at the bottom of the trench.

FIG. 18 shows a Device structure with low carbon vacancies and ion implanted boron for commercial SiC DMOSFET.

### DETAILED DESCRIPTION OF THE SUBJECT DISCLOSURE

The present subject disclosure addresses the shortcomings of conventional silicon carbide devices, as discussed above.

### Definitions

Before describing the present subject disclosure in detail, it is to be understood that the terminology used in the specification is for the purpose of describing particular embodiments, and is not necessarily intended to be limiting. Although many methods, structures and materials similar, modified, or equivalent to those described herein can be used in the practice of the present subject disclosure without undue experimentation, the preferred methods, structures and materials are described herein. In describing and claiming the present subject disclosure, the following terminology will be used in accordance with the definitions set out below.

As used herein, the singular forms “a”, “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±10% of that stated.

### Overview

Semiconductor devices include an epitaxial silicon carbide drift region having vertical current transport having a rectifying current injector or field effect transistor current injector on the upper portion of the drift layer and a lower portion having a contact on a substrate or contact on a drift layer to collect current.

In one exemplary embodiment, the drift region includes a superjunction structure that includes p-n junction junctions that have a composite p-type pillar region formed by ion implantation that has both aluminum and boron dopants with the boron dopants being deeper into the n-type drift layer. The advantage of the aluminum doped p-type pillar region is that the region will have a lower resistance than boron doped p-type pillar region because aluminum dopant has a lower ionization energy than boron dopant. Another advantage of aluminum dopants is that aluminum has approximately no diffusion in silicon carbide. The advantage of the boron doped p-type pillar region is that boron has a lower atomic mass than aluminum and thus can be implanted deeper into silicon carbide than aluminum. The aluminum portion of the p-type pillar layer may have a high dopant concentration upper portion and a moderate dopant concentration lower portion. The aluminum portion of the p-type pillar layer may have a high dopant concentration upper portion that performs as a p-type blocking junction.

The superjunction structure described herein can be used in a variety of settings, including but not limited to Junction Barrier Schottky (JBS) diode devices, PiN diode devices, field effect transistors, bipolar devices, insulated gate bipolar transistor devices, and thyristor device.

The composite P-type pillar layer is optionally co-implanted with carbon to enhance the activation of boron in the silicon lattice. The composite P-type pillar layer is optionally co-implanted with carbon to suppress the diffusion of boron.

Epitaxial regrowth can be performed on selected epitaxial layers known as bottom epitaxial layers.

The aluminum portion of the P-type pillar layer may be retrograde ion implanted so that the surface of the bottom epitaxial layer has minimized ion implant damage at the surface that facilitates the growth of high-quality epitaxial regrowth layers. The dose of the retrograde ion implanted aluminum dopant is selected to not amorphized the SiC at a depth of 100 nm below the SiC surface. The minimized ion implantation damage on the surface of the bottom epitaxial layer will allow improved quality of the epitaxial layer for an epitaxial regrowth layer. A hydrogen etch of approximately 100 nm of SiC is typically performed prior to the growth of the SiC epitaxial regrowth layer.

The epitaxial regrowth layer can be grown in a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the P-type pillar layer into the N-type channel.

The JBS, PiN or FET device can have a bottom epitaxial growth layer, multiple epitaxial regrowth layers and one upper epitaxial layer.

The N-type drift layer is optionally treated by a process by carbon ion implantation and anneal, high temperature oxidation, or annealing at approximately 9000 to reduce the carbon vacancies to reduce the diffusion of boron atoms in silicon carbide material.

The diffusion of boron is by a kick-out mechanism and the boron diffusing is a tail diffusion that has a lower boron concentration than non-diffused portion of the boron ion implanted region.

The superjunction region of the device comprises quasi-charge balance regions. The doping in the lower portion of the P-type pillar layer and the doping in the N-type channel may be selected to achieve quasi-charge balance. The doping concentration of the N-type channel regions is selected to achieve quasi-charge balance and also selected to be higher than then concentration of boron atoms that diffuse into the N-type channel region so that the N-type channel dopant overcompensates the diffused boron atoms in the N-type channel regions.

The ion implantation can optionally use channeling to achieve a deeper ion implanted p-type pillar region. The p-n junction extends within 4/−1.5° of a crystallographic axis of the silicon carbide material forming the drift region.

The N-type channel doping can be achieved by doping with nitrogen during epitaxial growth or by doping with nitrogen or phosphorous ion implantation, or by nitrogen or phosphorous channel ion implantation.

The low diffusion boron P-type pillar layer is optionally co-implanted with carbon to enhance the activation of boron in the silicon lattice. The low diffusion boron P-type pillar layer is optionally co-implanted with carbon to suppress the diffusion of boron. The carbon ion implantation dose can be a higher dose than the boron ion implantation dose. The ratio of the carbon ion implantation dose to the boron ion implantation dose may be in the range of may be in the 0.5:1 to 20:1. The carbon ion implantation dose can be in the range of 5×10¹² cm⁻² to 5×10¹⁴ cm⁻² and with an ion implantation energy in the range of 200 eV to 15 MeV. The low diffusion boron may have a diffusion rate that is in the range of 95 percent to 0.01 percent of the diffusion rate of boron. The low diffusion boron may have a diffusion coefficient that is in the range of 95 percent to 0.01 percent of the diffusion coefficient of boron. The diffusion coefficient of boron changes with temperature. For a temperature of 1700° C., the diffusion coefficient of boron in silicon carbide is 3×10⁻¹⁹ cm²s⁻¹ and for a temperature of 1800° C., the diffusion coefficient of boron in silicon carbide is 3×10⁻¹⁹ cm²s, Temperature in the range of 1200° C. to 2200° C. can be used to anneal boron ion implantation damage. Also, fast transient anneals with temperature in the range of 1200° C. to 2200° C. can be used to anneal boron ion implant damageEpitaxial regrowth can be performed on selected epitaxial layers known as bottom epitaxial layers. The low diffusion boron portion of the P-type pillar layer may be retrograde ion implanted so that the surface of the bottom epitaxial layer has minimized ion implant damage at the surface that facilitates the growth of high-quality epitaxial regrowth layers.

The dose of the retrograde ion implanted boron dopant is selected to not amorphized the SiC at a depth of 100 nm below the SiC surface. The minimized ion implantation damage on the surface of the bottom epitaxial layer will allow improved quality of the epitaxial layer for an epitaxial regrowth layer.

A hydrogen etch of approximately 100 nm of SiC is typically performed prior to the growth of the SiC epitaxial regrowth layer. The epitaxial regrowth layer can be grown a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the P-type pillar layer into the N-type channel.

The JBS, PiN or FET device can have a bottom epitaxial growth layer, multiple epitaxial regrowth layers and one upper epitaxial layer.

The N-type drift layer is optionally treated by a process by carbon ion implantation and anneal, high temperature oxidation, or annealing at approximately 9000 to reduce the carbon vacancies to reduce the diffusion of boron atoms in silicon carbide material. The diffusion of boron is by a kick-out mechanism and the boron diffusing is a tail diffusion that has a lower boron concentration than non-diffused portion of the boron ion implanted region.

The superjunction region of the device comprise quasi-charge balance regions. The doping in the lower portion of the P-type pillar layer and the doping in the N-type channel may be selected to achieve quasi-charge balance. The doping concentration of the N-type channel regions is selected to achieve quasi-charge balance and also selected to be higher than then concentration of boron atoms that diffuse into the N-type channel region so that the N-type channel dopant overcompensates the diffused boron atoms in the N-type channel regions.

The ion implantation can optionally use channeling to achieve a deeper ion implanted p-type pillar region. The p-n junction extends within 4/−1.5° of a crystallographic axis of the silicon carbide material forming the drift region. The N-type channel doping can be achieved by doping with nitrogen during epitaxial growth or by doping with nitrogen or phosphorous ion implantation, or by nitrogen or phosphorous channel ion implantation.

### SUMMARY

### Silicon Carbide Superjunction Device

The superjunction semiconductor devices are provided that include a 4H silicon carbide drift region that has an upper portion and a lower portion. A first contact is formed on the upper portion of the drift region and a second contact is formed on the lower portion of the drift region. The drift region includes a superjunction structure that includes a first pillar that is doped with first conductivity type impurities.

The superjunction semiconductor device includes a semiconductor drift region that has a plurality of interleaved n-type pillars and p-type pillars. The P-type pillars may comprise composite p-type pillar that utilizes a combination of aluminum and boron ion implantation or may comprise low diffusion boron p-type pillars that utilize boron ion implantation. N-type pillars may have n-type dopant concentration that overcompensate boron dopants that laterally diffuse into the N-type pillar region. In some embodiments, the N-type pillar may have a doping concentration more than approximately 3×10¹⁶ cm⁻³ to overcompensate boron dopants that laterally diffuse into the N-type pillar region.

The superjunction semiconductor device comprises having dopants having a second conductivity type that is opposite the first conductivity type are implanted into selected portions of the n-type drift layer. In some embodiments, the first implanted region may comprise a p-type pillar, and the second implanted region may comprise an n-type pillar that directly contacts the p-type pillar.

The superjunction semiconductor devices include an epitaxial silicon carbide drift region having vertical current transport having a rectifying current injector, field effect transistor current injector, or bipolar current injector on the upper portion of the drift layer and a lower portion having a contact on a substrate or contact on a drift layer to collect current.

In one embodiment, the drift region includes a superjunction structure that includes p-n junction junctions that have composite p-type pillar region formed by ion implantation that has both aluminum and boron dopants with the boron dopants being deeper into the n-type drift layer.

Because of this superjunction structure, the top portion of the N-type channels in the drift region can be doped more heavily than would otherwise be possible for a conventional structure. This enables the device to have lower on-state resistance than would otherwise be possible for a given pillar voltage.

The advantage of the aluminum doped p-type pillar region is that the region will have a lower resistance than boron doped p-type pillar region because aluminum dopant has a lower ionization energy than boron dopant. Another advantage of aluminum dopants is that aluminum has approximately no diffusion in silicon carbide.

The advantage of the boron doped p-type pillar region is that boron has a lower atomic mass than aluminum and thus can be implanted deeper into silicon carbide than aluminum.

The aluminum portion of the p-type pillar layer may have a high dopant concentration upper portion and a moderate dopant concentration lower portion. The aluminum portion of the p-type pillar layer may have a high dopant concentration upper portion that performs as a p-type blocking junction.

The composite P-type pillar layer is optionally co-implanted with carbon to enhance the activation of boron in the silicon lattice. The composite P-type pillar layer is optionally co-implanted with carbon to suppress the diffusion of boron.

The aluminum portion of the P-type pillar layer may be retrograde ion implanted so that the surface of the bottom epitaxial layer has minimized ion implant damage at the surface that facilitates the growth of high-quality epitaxial regrowth layers. The dose of the retrograde ion implanted aluminum dopant is selected to not amorphized the SiC at a depth of 100 nm below the SiC surface. The minimized ion implantation damage on the surface of the bottom epitaxial layer will allow improved quality of the epitaxial layer for an epitaxial regrowth layer.

A hydrogen etch of approximately 100 nm of SiC is typically performed prior to the growth of the SiC epitaxial regrowth layer. The epitaxial regrowth layer can be grown a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the P-type pillar layer into the N-type channel.

The JBS, PiN or FET device can have a bottom epitaxial growth layer, multiple epitaxial regrowth layers and one upper epitaxial layer.

The N-type drift layer is optionally treated by a process by carbon ion implantation and anneal, high temperature oxidation, or annealing at approximately 9000 to reduce the carbon vacancies to reduce the diffusion of boron atoms in silicon carbide material.

The diffusion of boron is by a kick-out mechanism and the boron diffusing is a tail diffusion that has a lower boron concentration than non-diffused portion of the boron ion implanted region.

The superjunction region of the device comprise quasi-charge balance regions. The doping in the lower portion of the P-type pillar layer and the doping in the N-type channel may be selected to achieve quasi-charge balance. The doping concentration of the N-type channel regions is selected to achieve quasi-charge balance and also selected to be higher than then concentration of boron atoms that diffuse into the N-type channel region so that the N-type channel dopant overcompensates the diffused boron atoms in the N-type channel regions.

The ion implantation can optionally use channeling to achieve a deeper ion implanted p-type pillar region. The p-n junction extends within 4/−1.5° of a crystallographic axis of the silicon carbide material forming the drift region. The N-type channel doping can be achieved by doping with nitrogen during epitaxial growth or by doping with nitrogen or phosphorous ion implantation, or by nitrogen or phosphorous channel ion implantation.

In one exemplary embodiment, the drift region includes a superjunction structure that includes p-n junction junctions that have low diffusion boron p-type pillar region formed by ion implantation that has both boron dopants and optionally aluminum dopants with the boron dopants being deeper into the n-type drift layer. The advantage of the aluminum doped p-type pillar region is that the region will have a lower resistance than boron doped p-type pillar region because aluminum dopant has a lower ionization energy than boron dopant. Another advantage of aluminum dopants is that aluminum has approximately no diffusion in silicon carbide. The advantage of the boron doped p-type pillar region is that boron has a lower atomic mass than aluminum and thus can be implanted deeper into silicon carbide than aluminum.

The p-type pillar may have an aluminum ion implanted portion or a boron ion implanted portion of the p-type pillar layer may have a high dopant concentration upper portion that performs as a blocking junction. The high boron or aluminum portion of the p-type pillar layer may have a high dopant concentration upper portion that performs as a p-type blocking junction.

The superjunction structure can be used in Schottky Barrier Junction (JBS) diode devices, PiN diode devices, field effect transistors, bipolar devices, insulated gate bipolar transistor devices, and thyristor device. The low diffusion boron P-type pillar layer is optionally co-implanted with carbon to enhance the activation of boron in the silicon lattice. The low diffusion boron P-type pillar layer is optionally co-implanted with carbon to suppress the diffusion of boron. Epitaxial regrowth can be performed on selected epitaxial layers known as bottom epitaxial layers. The low diffusion boron portion of the P-type pillar layer may be retrograde ion implanted so that the surface of the bottom epitaxial layer has minimized ion implant damage at the surface that facilitates the growth of high-quality epitaxial regrowth layers.

The dose of the retrograde ion implanted boron dopant is selected to not amorphized the SiC at a depth of 100 nm below the SiC surface. The minimized ion implantation damage on the surface of the bottom epitaxial layer will allow improved quality of the epitaxial layer for an epitaxial regrowth layer.

A hydrogen etch of approximately 100 nm of SiC is typically performed prior to the growth of the SiC epitaxial regrowth layer.

The epitaxial regrowth layer can be grown a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the P-type pillar layer into the N-type channel.

The JBS, PiN or FET device can have a bottom epitaxial growth layer, multiple epitaxial regrowth layers and one upper epitaxial layer.

The N-type drift layer is optionally treated by a process by carbon ion implantation and anneal, high temperature oxidation, or annealing at approximately 9000 to reduce the carbon vacancies to reduce the diffusion of boron atoms in silicon carbide material. The diffusion of boron is by a kick-out mechanism and the boron diffusing is a tail diffusion that has a lower boron concentration than non-diffused portion of the boron ion implanted region.

The superjunction region of the device comprise quasi-charge balance regions. The doping in the lower portion of the P-type pillar layer and the doping in the N-type channel may be selected to achieve quasi-charge balance. The doping concentration of the N-type channel regions is selected to achieve quasi-charge balance and also selected to be higher than then concentration of boron atoms that diffuse into the N-type channel region so that the N-type channel dopant overcompensates the diffused boron atoms in the N-type channel regions.

The ion implantation can optionally use channeling to achieve a deeper ion implanted p-type pillar region. The p-n junction extends within 4/−1.5° of a crystallographic axis of the silicon carbide material forming the drift region. The N-type channel doping can be achieved by doping with nitrogen during epitaxial growth or by doping with nitrogen or phosphorous ion implantation, or by nitrogen or phosphorous channel ion implantation.

Composite p-Type Pillar

The drift region includes a superjunction structure that achieves quasi-charge balance and that includes a p-n junction that is has a composite p-type pillar region formed by ion implantation that has both aluminum dopant portion and boron dopant portion with the boron dopants being in the lower portion of the P-type pillar. Because of this superjunction structure, the top portion of the N-type channels in the drift region can be doped more heavily than would otherwise be possible for a conventional structure. This enables the device to have lower on-state resistance than would otherwise be possible for a given pillar voltage. The boron dopant portion in the composite p-type pillar is deeper into the n-type drift layer that the aluminum dopant portion.

The advantage of the aluminum doped portion of the composite p-type pillar region is that the aluminum doped region will have a lower resistance than the boron doped portion of composite p-type pillar region because aluminum dopant has a lower ionization energy than boron dopant and thus a low resistivity.

The advantage of the boron doped portion of the composite p-type pillar region is that boron has a lower atomic mass than aluminum and thus can be ion implanted deeper into silicon carbide than aluminum ion implantation. The boron atomic mass of 10.8 amu and aluminum has an atomic mass of 26.9 amu. The Aluminum atomic mass is 2.74 times heavier than the boron atomic mass and thus boron atoms can be ion implanted approximately 2.74 times deeper than aluminum atoms. The aluminum portion of the composite p-type pillar layer may have a both a high dopant concentration upper portion that can perform as a P-type blocking layer and a moderated dopant concentration lower portion. The composite P-type pillar layer is optionally co-implanted with carbon to enhance to reduce carbon vacancies and improve the activation of boron in the silicon carbide lattice. Epitaxial regrowth can be performed on epitaxial layers known as bottom epitaxial layers.

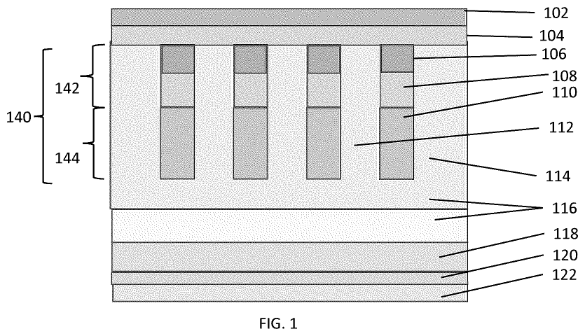

The composite p-type pillar may comprise a highly aluminum doped p-type region in an upper portion of the n-type drift region. As shown in FIG. 1, in some embodiments, the p-type blocking junction may substantially or completely cover a top surface of the p-type silicon carbide pillar. The p-type blocking junction may also partially cover a top surface of the n-type silicon carbide pillar. The p-type blocking junction may reduce the electric field to help shield the Schottky contact from the electric field when the JBS diode operates in the high voltage blocking state.

A n-type channel may be provided between the p-type composite pillars and the Schottky contact. Current flows through the n-type channel when the JBS diode is in its on-state. The superjunction device with composite p-type pillars may incorporate, for example, a planar DMOSFET, UMOSFET, JFET, BJT, or thyristor type structure to allow controllable flow of current through the device.

The n-type pillars and p-type composite pillars may extend much deeper than the pillars that are included in superjunction structures of conventional 4H silicon carbide semiconductor devices. The reason for this is that the n-type and p-type dopants are implanted into the silicon carbide at angles that allow for channeling to occur so that the dopant ions may be implanted deeper into the device, as is discussed above with respect to a single ion implantation step. As discussed above, these deeper implants allow faster fabrication of power semiconductor devices that have thick superjunction type drift layers. The thicker drift layers increase the voltage pillar capabilities of the device, while the superjunction structure helps reduce or eliminate any offsetting increase in the on-state resistance of the device that would otherwise occur as a result of the increased thickness of the drift layer.

The aluminum high doped upper portion of each p-type pillar junction may generate strong electric fields during reverse pillar operation that perform as an electric field shield to shield the Schottky barrier from high electric fields and that may resist high reverse voltages.

The aluminum moderate-doped and boron moderate-doped lower portion of each p-type pillar junction may have a doping concentration that is selected to achieve a quasi-charge balance with respect to the n-type channel regions that are interposed therebetween. The lower portions of the channel regions and the lower portions of the aluminum and boron p-type pillar junctions may form a superjunction structure that comprises a series of p-n junctions that exhibit low resistance while still maintaining a high reverse breakdown voltage. By “quasi-charge balanced” it is meant that the charge of the lower aluminum and boron p-type pillar junctions approximately equals the charge of the channel regions. Approximately equal is for example, within 20% of each other—then the lower portions of the aluminum and boron p-type pillar junctions and the channel regions therebetween may act like a superjunction, thereby reducing the conventional tradeoff between on-state resistance and reverse voltage pillar performance.

Low Boron Diffusion p-Type Pillar or N-Type Pillar that Overcompensated Lateral Boron Diffusion

Boron is known to diffuse in SiC at higher temperature greater than approximately 16000. Aluminum dopant is often used to form P-type wells for SiC MOSFETs or P-type pillars of a superjunction SiC device because the aluminum does not diffuse at temperatures below approximately 18000. The disadvantage of diffusion of the P-type dopant is that the P-type dopant can diffuse laterally and block the current flow in a SiC MOSFET but overcompensating the N-type JFET region of a SiC MOSFET or the N-type channel of a SiC superjunction device. Boron can have low diffusions by reducing the density of carbon vacancies in silicon carbide epitaxial layers.

The drift region includes a superjunction structure that achieves quasi-charge balance and that includes a p-n junction that is has a low diffusion p-type pillar region formed by boron ion implantation that optionally has a high boron dopant portion in the upper portion of the low diffusion P-type pillar. The low boron dopant portion in the composite p-type pillar is deeper into the n-type drift layer than the high dopant portion. The advantage of the high boron doped portion of the low diffusion p-type pillar region is that the high boron doping can perform as a P-type blocking region. The advantage of the boron doped portion of the composite p-type pillar region is that boron has a lower atomic mass than aluminum and thus can be ion implanted deeper into silicon carbide than aluminum ion implantation. The boron atomic mass of 10.8 amu and aluminum has an atomic mass of 26.9 amu. The Aluminum atomic mass is 2.74 times heavier than the boron atomic mass and thus boron atoms can be ion implanted approximately 2.74 times deeper than aluminum atoms. The high boron portion of the low diffusion p-type pillar layer may have a both a high dopant concentration upper portion that can perform as a P-type blocking layer and a moderated dopant concentration lower portion. The low boron diffusion P-type pillar layer is optionally co-implanted with carbon to enhance to reduce carbon vacancies and improve the activation of boron in the silicon carbide lattice.

The diffusion of boron is by a kick-out mechanism and the boron diffusing is a tail diffusion that has a lower boron concentration than the non-diffused boron. Boron diffusion can be reduced by reducing the density of carbon vacancies in the silicon carbide. The N-type drift layer may be treated by a process to reduce the carbon vacancies to reduce the diffusion of boron atoms in silicon carbide material. Treatment processes that reduce carbon vacancies include carbon ion implantation and anneal, high temperature oxidation at a temperature more than 14000, or annealing at approximately 9000. The carbon vacancy reduction treatment process to reduce the carbon vacancies can be performed on each epitaxial growth or can be performed after the epitaxial layers have been grown.

Low Boron Diffusion p-Type Pillar or N-Type Pillar that Overcompensated Lateral Boron Diffusion

Approaches to achieve low boron diffusion include:
Reduction of carbon vacancies in the silicon carbide epitaxial layer
Fast transient annealing to minimize lateral diffusion
Low temperature epitaxial growth

The boron diffusion can also be reduced using low temperature epitaxial growth for epitaxial layers. Low temperature epitaxial growth can also be used to reduce the boron diffusion. Boron does not diffuse in silicon carbide for lower temperatures such as 1300 C. The epitaxial regrowth layer can be grown a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the composite P-type pillar layer into the N-type channel.

Anneal temperature of approximately 1550 C for continuous time anneal are needed to activate boron.

An additional approach for low boron diffusion is to use fast transient anneals. Fast transient anneals can also activate boron dopant with minimal boron diffusion. Fast transient anneal techniques include microwave annealing, microwave plasma annealing, fast inductive heating, laser annealing, and rapid thermal annealing. Argon or nitrogen ambient can improve the cooling rate. Microwave anneal at approximately in the range of 16000 to 2000 C for approximately 10 to 30 seconds can activate boron dopants.

The approach to use an N-type pillar to overcompensate lateral boron diffusion is to have an N-type pillar doping concentration in the range approximately 3×10¹⁶ cm⁻³ to 1×10¹⁷ cm⁻³ doping concentration. Boron diffusion in silicon carbide is by a kickout diffusion mechanism and the diffused portion of a boron ion implanted region typically has a peak concentration in the range of less than 3×10¹⁶ cm⁻³ to 1×1017 cm−3. Thus, if the boron diffusion is made into a N-type pillar region that has a higher dopant concentration then the laterally diffused boron, the N-type doping will overcompensate the P-type boron doping and the region will remain N-type. Thus, a doping in the N-channel region (N-channel pillar) of a SiC superjunction device in the range approximately 3×10¹⁶ cm⁻³ to 1×10¹⁷ cm⁻³ doping concentration will overcompensate the lateral boron diffusion dopants.

Typically, boron has a high diffusion rate in silicon carbide. Boron can be used in the p-type pillar of SiC superjunctions transistors if the boron that is used to form the p-type pillar is a low diffusion boron. Also, the offset of the P-type pillar from the edge of the P-well for the SiC DMOS, SiC UMOSFET, or SiC CoolMOSFET can be reduced by the using the processes to form the low diffusion p-type pillar. The processes used to form the low diffusion boron P-type pillar include, for example:
Reduction of carbon vacancies in the silicon carbide epitaxial layer
Fast transient annealing to minimize boron lateral diffusion
Low temperature epitaxial growth

The low diffusion P-type pillar reduces the electric field in the gate insulator on the bottom of the UMOSFET and COOLMOSFET gate structure. The low diffusion P-type pillar also reduces the electric field in the n-type JFET region. The low diffusion boron has low lateral diffusion so that the offset of the P-type p-type pillar from the edge of the P-well can be reduced. The offset can be in the range of approximately zero microns to approximately 3 microns. It is advantages to reduce the offset dimension because a smaller offset allows a smaller unit cell dimension and thus higher power device current capability performance. The use of boron for the P-type pillar of a UMOSFET or COOLMOSFET is advantages since the boron can be implanted approximately 2.7 times deeper than the aluminum ion implanted P-well using converntional ion implanters with accelleration of dopant ions energies in the range of 200 keV to 750 keV. The deeper boron P-type pillar provides a higher level of electric field shielding of the gate insulator at the bottom of the U-shaped trench.

### Superjunction Quasi-Charge Balance

Because of this superjunction structure, the top portion of the N-type channels in the drift region can be doped more heavily than would otherwise be possible for a conventional structure. This enables the device to have lower on-state resistance than would otherwise be possible for a given pillar voltage.

The doping in the lower portion of the composite P-type pillar layer and the doping in the N-type channel are selected to achieve quasi-charge balance. The doping concentration of the N-type channel regions is selected to achieve quasi-charge balance and also selected to be higher than then concentration of boron atoms that diffuse laterally into the N-type channel region so that the N-type channel dopant overcompensates the laterally diffused boron atoms in the N-type channel regions.

In some embodiments, the first p-type pillar and the second n-type pillar may form a p-n junction in the drift region that is at least part of a superjunction structure in the drift region.

In some embodiments, the first sidewall of the first pillar may be coplanar with the first sidewall of the second pillar. A first volume of the first pillar may be approximately equal to a second volume of the second pillar. The semiconductor device may further include a silicon carbide substrate that is between the drift region and the second contact. The first conductivity type impurities may be p-type conductivity impurities and the second conductivity type impurities may be n-type conductivity impurities.

The first and second pillars may extend at least 4 microns into the drift region from an upper surface of the drift region using conventional ion implantation but may extend up to approximately 100 microns using high energy ion implantation, boron dopants, and ion implant channeling. The drift region may have a doping concentration of, for example, from about 5×10¹⁵ cm⁻³ to about 5×10¹⁷ cm⁻³. The first pillar may have a doping concentration that varies as a function of depth from an upper surface of the drift region by less than a factor of ten throughout at least a 2.5 micron deep portion of the first pillar.

In some embodiments, the first pillar and the second pillar may have approximately the same width. The first and second pillars may extend up to approximately 100 microns into the drift region from an upper surface of the drift region. The first pillar may have a doping concentration that varies as a function of depth from an upper surface of the drift region by less than a factor of ten throughout at least a 2.5 micron deep portion of the first pillar.

Pursuant to embodiments of the present subject disclosure, deep p-type implants may be performed to form the p-type pillar junctions where the implanted regions have doping profiles that may be carefully selected to achieve a quasi-charge balance to the n-type drift region. In this fashion, a superjunction structure may be formed in the drift region. The superjunction structure may act like a series of p-n junctions that exhibit low resistance while still maintaining a high reverse breakdown voltage. The superjunction structure may be formed to extend only partially through the drift region, to avoid a potential decrease in the reverse breakdown voltage that may occur if the thickness of the drift region is effectively reduced too much by the superjunction structure. Such an embodiment of the present subject disclosure will now be described in further detail.

The highly doped upper portion of each p-type pillar junction, p-type blocking junction, may generate strong electric fields during reverse pillar operation that may resist high reverse voltages. The moderately-doped lower portion of each p-type pillar junction may have a doping concentration that is selected to achieve a quasi-charge balance with respect to the n-type channel regions that are interposed therebetween. The lower portions of the channel regions and the lower portions of the p-type pillar junctions may form a superjunction structure that comprises a series of p-n junctions that exhibit low resistance while still maintaining a high reverse breakdown voltage. The p-type pillar junctions only extend partially through the drift region. By “quasi-charge balanced” it is meant that the charge of the p-type pillar junctions approximately equals the charge of the channel regions. It has been discovered that as long as these charges are approximately equal—for example, within 20% of each other —then the lower portions of the p-type pillar junctions and the channel regions therebetween may act like a superjunction, thereby reducing the conventional tradeoff between on-state resistance and reverse voltage pillar performance.

### Dopant Ion Implantation

The ion implantation will be optionally be performed using channeled ion implantation. The channeled ion implantation utilizes performing ion implantation at a selected angle to the single-crystal semiconductor lattice so that the ions penetrate into the semiconductor material lattice through channels in the single-crystal semiconductor lattice achieving large penetration depth and reduced damage to the single crystal semiconductor lattice. The channeling ion implantation is used to achieve a deeper aluminum ion implantation and also a deeper boron ion implantation that produces a deeper composite P-type pillar layer or deeper low diffusion p-type pillars. Deeper P-type pillar layers allow a thicker epitaxial regrowth layer and thus reduce the number of epitaxial growth layers need to achieve a selected drift layer thickness. Reducing the number epitaxial regrowth layers is advantageous for a lower manufacturing cost.

An optional carbon coimplant that may be performed along with a boron ion implant into the same window in masking material as the boron ion implant may also be performed as a channeled ion implant. The optionally carbon implant may also be performed as a blanket ion implant or a blanket channeled ion implant. The carbon ion implantation dose can be in the range of 5×10¹² cm⁻² to 5×10¹⁴ cm⁻² and with an ion implantation energy in the range of 200 eV to 15 MeV.

The ion implantation will typical be performed by a multi-step ion implantation with each step of the ion implantation having a different energy and different dose often with the goal of producing a box dopant profile but can produce dopant profile multi-region dopant profile or variable dopant profile with depth. The ion implantation can be performed with convention ion implantation tools using energies in the range of approximately 200 keV to 1000 keV but can also be performed with high energy ion implantation with energies of approximately 1 MeV to approximately 15 MeV.

In some embodiments, the ion implantation may be performed at room temperature. In some embodiments, the ion implantation may be performed at an elevated temperature in the range of approximately 4000 to 1100 C. The elevated temperature ion implantation are advantages to anneal some of the ion implantation damage during the ion implantation process and that enables improved ion implantation dopant activation and reduced ion implantation damage.

An ion implantation energy filter may be used to reduce the number of steps of the ion implantation. The energy filter is a micropatterned membrane, which converts a monoenergetic ion beam into a continuum of ion implant energies so that a single ion implantation step can be used to achieve a continuum of ion implantation depth. The micropatterned membrane that implements the energy filter should be aligned to the surface of the silicon carbide wafer to less than approximately 2 degrees to use the energy filter for channeled ion implants.

Significantly thinner implant masks may be used when channeled ion implantation is performed, because the implant energies may be lower than would otherwise be required to achieve similar implant ranges. In some cases, the implant mask may be less than half the thickness that would otherwise be required to obtain similar implant ranges. For such an implant energy of 5 MeV, a SiO2 mask having a thickness of 5.0 microns would typically be used to ensure ions are only implanted into the unmasked areas. For such an implant energy of 750 keV, a SiO2 mask having a thickness of 2.0 microns would typically be used to ensure ions are only implanted into the unmasked areas. SiO2 mask is desirable because SiO2 is compatible with a high temperature ion implantation. Other masking materials include amorphous silicon, polysilicon, metal oxides, metal nitride, metal, or metal alloys. The masking material layers may be deposited using chemical vapor deposition, physical vapor deposition, electroplating, or electroless plating. Polycrystalline silicon grown by chemical vapor deposition often has columnar grains that are undesirable for use as a mask for high energy ion implantation. Non-columnar grain amorphous silicon is a desirable masking material for high energy ion implantation.

The multi-step channeling implant may have several advantages. First, the implant may be performed at room temperature, which may reduce manufacturing costs. Additionally, the channeled implant may result in significantly less damage to the silicon carbide crystal, as the ions penetrate deep into the crystal with greatly reduced scattering (which causes crystal damage), and the ions arc primarily slowed and stopped within the crystal lattice due to electron cloud interactions. The p-type dopants may achieve very high activation levels, such as activation levels in excess of 95% since the channeled implant facilitates implanting ions more consistently into electrically active locations within the crystal lattice. The channeled implant allows the formation of a deep junction with a relatively flat doping profile. This doping profile may facilitate forming a generally charge-balanced superjunction structure deep within the drift region that may reduce the on-resistance of the JBS diode (or other device), and which may reduce the electric field intensity at the Schottky junction, allowing for use of a lower Schottky barrier height Schottky contact.

The multi-step channeling implant may have several advantages. First, the implant may be performed at room temperature, which may reduce manufacturing costs. Additionally, the channeled implant may result in significantly less damage to the silicon carbide crystal, as the ions penetrate deep into the crystal with greatly reduced scattering (which causes crystal damage), and the ions arc primarily slowed and stopped within the crystal lattice due to electron cloud interactions. The p-type dopants may achieve very high activation levels, such as activation levels in excess of 95% since the channeled implant facilitates implanting ions more consistently into electrically active locations within the crystal lattice. The channeled implant allows the formation of a deep junction with a relatively flat doping profile. This doping profile may facilitate forming a generally charge-balanced superjunction structure deep within the drift region that may reduce the on-resistance of the JBS diode (or other device), and which may reduce the electric field intensity at the Schottky junction, allowing for use of a lower Schottky barrier height Schottky contact. Additionally, the multistep nature of the ion implantation process allows the formation of more heavily doped p-type regions in the upper surface of the drill region that support high reverse pillar voltage levels.

### Retrograde Aluminum or Boron Ion Implantation to Minimize Defects at the Surface of the Bottom Epitaxial Layer to Improve Epitaxial Regrowth Material

The upper portion of the aluminum portion of the composite P-type pillar layer may be retrograde ion implanted below the silicon carbide surface with the concentration of aluminum at the epitaxial layer surface less than 1×10¹⁸ cm³ so that the surface of the bottom epitaxial layer has minimized ion implant damage at the surface. The low defect density at the surface of the bottom epitaxial layer facilitates the growth of high-quality epitaxial regrowth layer on the bottom epitaxial layers. There will typically be a hydrogen etch that removes approximately a 100 nm of the bottom epitaxial layer surface during the epitaxial regrowth process. The aluminum retrograde ion implant concentrations should have a concentration less than 1×10¹⁸ cm³ at the location of the deepest hydrogen etch depth. The minimized ion implant damage on the surface of the bottom epitaxial layer will allow improved quality of the epitaxial regrowth layer. The P-type pillar ion implantation that is made into the epitaxial regrowth layer extends beyond the thickness of the epitaxial regrowth layer into the P-type pillar in the bottom epitaxial layer so that there is continuous P-type dopant from the P-type pillar in the epitaxial regrowth layer to the P-type pillar in the bottom epitaxial layer.

### Low Temperature Epitaxial Regrowth Layer

The epitaxial regrowth layer can be grown a temperature in the range of approximately 1350 C to 1650 C. In some embodiments, the epitaxial regrowth layer can be grown in the range of 1350 C to 1550 C using chlorinated precursors. The advantage of epitaxial growth at 1350 C to 1550 C is reduced lateral diffusion of boron from the composite P-type pillar layer into the N-type channel.

### Multiple Epitaxial Regrowth Layers

The JBS, PiN or FET device can have bottom epitaxial growth layer, multiple epitaxial regrowth layers and one upper epitaxial regrowth layer. Composite p-type pillars or low diffusion boron p-type pillars may be made in each of the epitaxial layers. The aluminum or boron dopant may be a retrograde ion implant. In some embodiments, the p-type pillars do not extend through the entire thickness of the N-type drift layer.

### Epitaxial Layer Treated to Reduce Carbon Vacancies to Reduce Lateral Diffusion of Boron Atoms

The N-type drift layer is optionally treated by a process to reduce the carbon vacancies to reduce the diffusion of boron atoms in silicon carbide material. Treatment processes that reduce carbon vacancies include carbon ion implantation and anneal, high temperature oxidation at a temperature more than 14000, or annealing at approximately 9000. The diffusion of boron is by a kick-out mechanism and the boron diffusing is a tail diffusion that has a lower boron concentration than the non-diffused boron.

### N-Channel Pillar

The N-type channel pillar doping can be achieved by doping with nitrogen during epitaxial growth or by doping with nitrogen or phosphorous ion implantation, or by nitrogen or phosphorous channel ion implantation. Because of this superjunction structure, the top portion of the N-type channels in the drift region can be doped more heavily than would otherwise be possible for a conventional structure. This enables the device to have lower on-state resistance than would otherwise be possible for a given pillar voltage.

### Device Types

Embodiments of the present subject disclosure have been discussed above with reference to example embodiments in the form of JBS diodes and power DMOSFET or UMOSFET. However, it will be appreciated that other power semiconductor devices such as, for example, Schottky diodes, PiN diodes, Junction Field Effect Transistors, (JFETs), Bipolar transistors, Insulated Gate Bipolar Transistors, and thyristors.

FIG. 1 is a schematic cross-sectional diagram of a power semiconductor device in the form of a JBS diode that has a superjunction-type drift region formed using composite P-type pillar region and the channeling ion implantation techniques according to embodiments of the present subject disclosure. In the embodiment shown 102 is an anode metal electrode. 104 is a Schottky metal 106 is a P-type aluminum high doped concentration 1 blocking junction region of p-type pillar. 108 is P-type aluminum high doped concentration 1 blocking junction region of p-type pillar. 110 is P-type boron moderate doped region of p-type pillar optionally co-implanted with carbon to reduce carbon vacancies and suppress boron diffusion. 112 is N-type channel region with selected n-type doping concentration to achieve quasi-charge balanced on overcompensate lateral boron diffusion. 114 is N-type epitaxial drift layer that has been optionally treated to reduce carbon vacancy less than 1×1015 cm−2 to suppress boron diffusion. 116 is N-type epitaxial drift layer. 118 is N-type substrate. 120 is Ohmic metal. 122 is Cathode metal electrode. The superjunction structure 140 comprises a top layer 142 and bottom layer 144. Top layer 142 may be 0.2 μm to 20 μm, and bottom layer 144 may be 0.1 μm to 40 μm.

### JBS Structure

As shown in FIG. 1, the JBS diode includes a substrate, a drift region that includes a superjunction structure, contact layers, a composited p-type pillar junction and a n-type channel region. The substrate may comprise a 4H silicon carbide semiconductor wafer that has an upper surface and a lower surface. The substrate may be doped with n-type impurities (i.e., an n+ silicon carbide substrate). The impurities may comprise, for example, nitrogen or phosphorous. The doping concentration of the substrate may be, for example, between 1×10¹⁸ atoms/cm³ and 1×10²¹ atoms/cm³. The substrate may be any appropriate thickness (e.g., between 100 and 500 microns thick).

### Pursuant to Further Embodiments of the Present Subject Disclosure, Power Silicon Carbide Based Junction Barrier

Schottky (JBS) diodes are provided that may exhibit improved performance. The JBS diodes according to these embodiments of the present subject disclosure may have deeply implanted p-type wells that are implanted with p-type dopants such as aluminum, boron, gallium, indium or the like. In some embodiments, these p-type blocking regions may have a depth in excess of 2 microns. In other embodiments, the p-walls may have a depth in excess of 3 microns. The doping profiles of the deep implants may be selected to provide a quasi-charge balance to an n-type drift layer of the device, thereby providing enhanced performance.

The above-described JBS diodes and various other power semiconductor devices according to embodiments of the present subject disclosure may be fabricated using multi-step channeled ion implantation techniques to form deeply implanted regions that have unique and desirable doping profiles. These devices formed using these techniques may be silicon carbide power semiconductor devices in some embodiments. The power semiconductor devices according to these embodiments of the present subject disclosure may exhibit improved performance such as decreased power dissipation, lower leakage current and/or improved reverse breakdown voltage performance as compared to conventional power semiconductor devices. In some embodiments, the devices may be formed using a two-step ion implantation process where the ions are implanted using channeling techniques in at least one of the two ion implantation steps. A first step of the multi-step ion implantation process may implant ions at a relatively high implantation energy, while a second step of the multi-step ion implantation process may implant ions at a lower implantation energy. This technique may be used to achieve desired implant profiles that improve the performance of the device.

### N-Type Drift Region

The n-type drift region may comprise, for example, a silicon carbide n-type drift region that is epitaxially grown on the upper surface of the substrate. In example embodiments, the drift region may be between 3 and 200 microns thick. The drift region includes a superjunction structure that comprises at least a first n-type silicon carbide pillar and a first p-type silicon carbide composite pillar. While not shown in FIG. 1, it will be appreciated that two or more n-type pillars and/or two or more p-type composite pillars may be provided. The number of n-type pillars and p-type composite provided will be a function of the width selected for the pillars. Typically, each n-type pillar and p-type composite pillar will have the same width, although embodiments of the present subject disclosure are not limited thereto. The superjunction-type drift region may be designed to be charge balanced between the alternating n-type and p-type composite pillars in some embodiments.

The entirety of the drift region may be an epitaxial layer with selected N-type doping concentration. The entirety of the drift region may be an ion implanted region with N-type and P-type dopant. However it will be appreciated that this need not be the case. For example, in other embodiments, only an upper portion of the n-type drift region may be implanted. An example of a power semiconductor device according to embodiments of the present subject disclosure that has an n-type drift region that is not implanted throughout its entire depth is discussed below with reference to FIG. 1. It will also be appreciated that the doping concentration of the implanted portion of the drift region tends to decrease with increased distance from the upper surface of the device.

### Contact Layers

Referring again to FIG. 1, the contact layers include an ohmic contact layer that is on the bottom surface of the substrate, a cathode contact that is on the ohmic contact layer, a Schottky contact layer that is on a top surface of the drift region, and an anode contact that is on the Schottky contact layer. The ohmic contact layer may comprise a material that forms an ohmic contact to the n-type substrate. For example, if the substrate comprises a heavily doped n-type silicon carbide substrate, the ohmic contact layer may comprise a silicon/cobalt layer. The cathode contact may comprise a highly conductive metal contact such as a silver layer. In some embodiments, the cathode contact may comprise a multilayer metal structure such as, for example, a Ti/Ni/Ag structure. In some embodiments, the substrate may be partially or completely removed prior to formation of the ohmic contact layer and the cathode contact.

The Schottky contact layer may comprise a conductive layer that forms a Schottky contact with the silicon carbide drift region. In some embodiments, the Schottky contact layer may comprise a nickel layer. The anode contact may comprise a highly conductive metal contact such as an aluminum layer.

### Enhance Electrical Activity of Boron Dopants and Suppress Diffusion of Boron by Reducing Carbon Vacancies

In order to enhance the electrical activity of B acceptors, an optimized annealing temperature has to be used, which represents a compromise between out diffusion of B atoms and generation of electrically active B acceptors. The highest electrical activity of boron dopants is achieved for boron atom occupies preferentially silicon lattice sites. A co-implantation of carbon atoms removes carbon vacancies and forces the boron atoms to move to the silicon lattice sites during annealing. During the annealing step, mobile intrinsic interstitials and interstitial boron atoms compete in recombining with vacancies. The probability to incorporate B atoms in the silicon or carbon lattice site is governed by the surplus of the particular competing silicon or carbon intrinsic species by a site competition effect.

### Junction Termination

In some embodiments, the device may further include an edge termination that surrounds the first and second pillars.

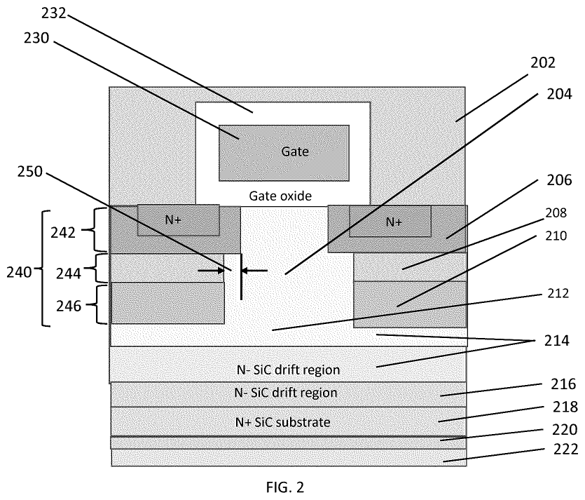

While the above examples focus on JBS diodes, it will be appreciated that the multi-step channeled implants according to embodiments of the present subject disclosure may be used to fabricate other devices such as, for example, PiN diodes. It will also be appreciated that the implant techniques discussed herein may be used to form deeply implanted termination structures such as the deeply implanted guard rings included in the JBS diode. Moreover, these techniques may also be used in other devices such as in MOSFETs where deep p-wells may be provided in order to allow for JFET regions and the N-type pillar regions of the MOSFET to have lower resistance values. An example of such a device will now be described with reference to FIG. 2.

### MOSFET

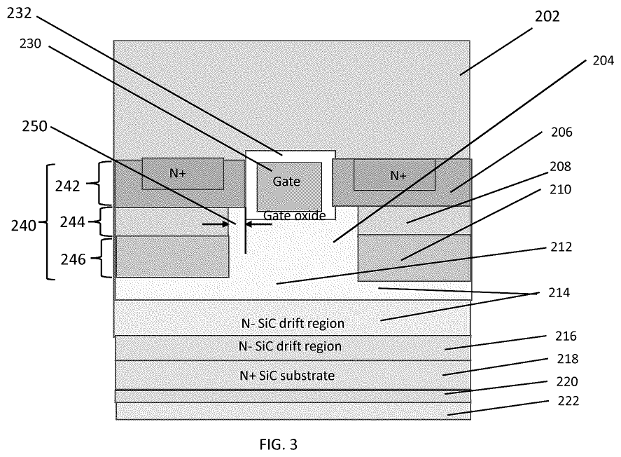

Another exemplary device according to embodiments of the present subject disclosure is shown in FIG. 3. The device shown in FIG. 2 is a MOSFET that has various regions that can be formed by ion implantation. This figure shows a superjunction SiC DMOSFET with composite P-type pillar.

202 is a source metal electrode. 204 is N-type channel region with selected n-type doping concentration to achieve quasi-charge balanced on overcompensate lateral boron diffusion. 206 is P-type aluminum high doped concentration 1 blocking junction region of P-type pillar. 208 is P-type aluminum moderate doped concentration 2 region of p-type pillar. 210 is P-type boron moderate doped region of p-type pillar optionally coimplanted with carbon to reduce carbon vacancies and suppress boron diffusion. 212 is N—SiC current spreading layer that has optionally been treated to reduce carbon vacancy less than 1×1015 cm−2. 214 is N-type epitaxial drift layer that has been optionally treated to reduce carbon vacancy less than 1×1015 cm−2. 216 is N-type epitaxial drift layer. 218 is N-type substrate. 220 is Ohmic metal. 222 is Drain metal electrode. 230 is gate that is embedded in gate oxide 232. 240 is Superjunction structure. Layer 242 is 0.5 μm. Layer 244 is 0.1 μm to 20 μm. Layer 246 is 0.1 μm to 40 μm. 250 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to 3 microns.

FIG. 2 is a cross-sectional diagram of a unit cell of a power MOSFET according to further embodiments of the present subject disclosure.

As shown in FIG. 2, the unit cell may be implemented on a heavily doped (n+) single crystal n-type silicon carbide substrate. A lightly doped (n+) silicon carbide drift region is provided on the substrate. The silicon carbide drift region is typically formed by epitaxial growth on the silicon carbide substrate. An n-type silicon carbide current spreading layer is provided on the n+ silicon carbide drift layer. The current spreading layer may be formed, for example, by epitaxial growth after formation of the n− silicon carbide drift layer in order to provide a moderately-doped current spreading layer that has a doping concentration that exceeds the doping concentration of the more lightly doped n′ silicon carbide drift layer. A pair of spaced apart p-type silicon carbide wells (“p-wells”) may then be formed in the upper surface of the n-type current spreading layer. The p-wells may be formed by implanting p-type ions into upper regions of the n-type current spreading layer using the above-described multi-step channeled ion implantation techniques. Each p-well may have a heavily doped upper portion blocking junction and a more moderately doped lower portion. An n− type silicon carbide JFET region may be provided in an upper, central portion of the current spreading layer between the p-wells and may be formed by ion implantation of N-type dopant.

The upper portion of each p-well may be heavily doped. For example, in some embodiments, the upper portion of each p-well may have a doping concentration of between 2×1017 cm−3 and 1×1020 cm−3. The lower portion of each p-well may have a moderate doping concentration. For example, in some embodiments, the lower portion of each p-well may have a doping concentration of between 5×1016 cm−3 and 5×1017 cm−3. The lower portion of each p-well may be quasi-charge balanced with the n-type current spreading layer to form a superjunction structure. This provision of the superjunction structure allows the JFET region to be more heavily doped without reducing the on-state resistance and without increasing the electric field intensity within the gate insulator. The doping concentration of the JFET region may, for example, be more than an order of magnitude greater than a doping concentration of the remainder of the current spreading layer.

A heavily doped (n+) n-type silicon carbide region is formed within the upper portion of each p-well. The heavily doped (n+) n-type silicon carbide regions act as the source regions for the two individual transistors included in the unit cell, while the current spreading layer, the drift region and the substrate together act as a common drain region for the unit cell. A channel region is provided in each p-well between the source region and the JFET region. A gate insulating layer (e.g., a silicon oxide layer) is provided on the JFET region, portions of the p-wells and portions of the n-type silicon carbide regions. A semiconductor or metal gate electrode is provided on the gate insulating layer. The gate insulating layer may surround the gate electrode in some embodiments. A source contact (e.g., a metal layer) is provided on the n+ source regions that acts as a common source contact, and a drain contact (e.g., another metal layer) is provided on the back side of the n+ silicon carbide substrate acts as the common drain contact.

FIG. 3 shows a Superjunction SiC UMOSFET with composite P-type pillar and low diffusion boron P-type pillar. The low diffusion P-type pillar reduces the electric field in the gate oxide on the bottom of the UMOSFET gate structure. 202 is a source metal electrode. 204 is N-type channel region with selected n-type doping concentration to achieve quasi-charge balanced on overcompensate lateral boron diffusion. 206 is P-type aluminum high doped concentration 1 blocking junction region of P-type pillar. 208 is P-type aluminum moderate doped concentration 2 region of p-type pillar. 210 is P-type boron moderate doped region of p-type pillar optionally coimplanted with carbon to reduce carbon vacancies and suppress boron diffusion. 212 is N—SiC current spreading layer that has optionally been treated to reduce carbon vacancy less than 1×1015 cm−2. 214 is N-type epitaxial drift layer that has been optionally treated to reduce carbon vacancy less than 1×1015 cm−2. 216 is N-type epitaxial drift layer. 218 is N-type substrate. 220 is Ohmic metal. 222 is Drain metal electrode. 230 is gate that is embedded in gate oxide 232. 240 is Superjunction structure. Layer 242 is 0.5 μm. Layer 244 is 0.1 μm to 20 μm. Layer 246 is 0.1 μm to 40 μm. 250 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to 3 microns.

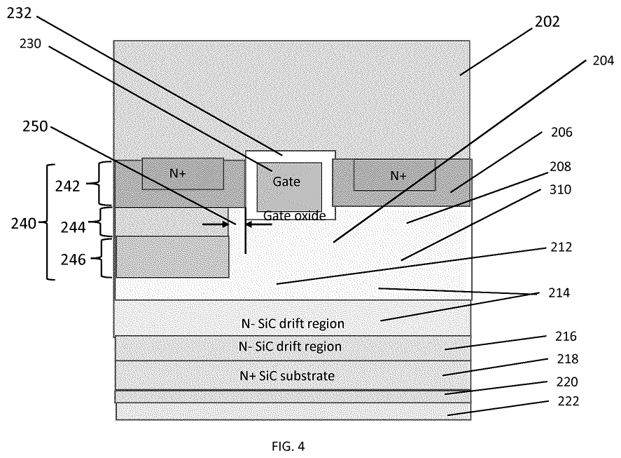

FIG. 4 shows a Superjunction SiC CoolMOSFET with composite P-type pillar and low diffusion boron. The low diffusion P-type pillar reduces the electric field in the gate oxide on the bottom of the UMOSFET gate structure. 202 is a source metal electrode. 204 is N-type channel region with selected n-type doping concentration to achieve quasi-charge balanced on overcompensate lateral boron diffusion. 206 is P-type aluminum high doped concentration 1 blocking junction region of P-type pillar. 208 is P-type aluminum moderate doped concentration 2 region of p-type pillar. 210 is P-type boron moderate doped region of p-type pillar optionally co-implanted with carbon to reduce carbon vacancies and suppress boron diffusion. 212 is N—SiC current spreading layer that has optionally been treated to reduce carbon vacancy less than 1×1015 cm−2. 214 is N-type epitaxial drift layer that has been optionally treated to reduce carbon vacancy less than 1×1015 cm−2. 216 is N-type epitaxial drift layer. 218 is N-type substrate. 220 is Ohmic metal. 222 is Drain metal electrode. 230 is gate that is embedded in gate oxide 232. 240 is Superjunction structure. Layer 242 is 0.5 μm. Layer 244 is 0.1 μm to 20 μm. Layer 246 is 0.1 μm to 40 μm. 250 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to 3 microns.

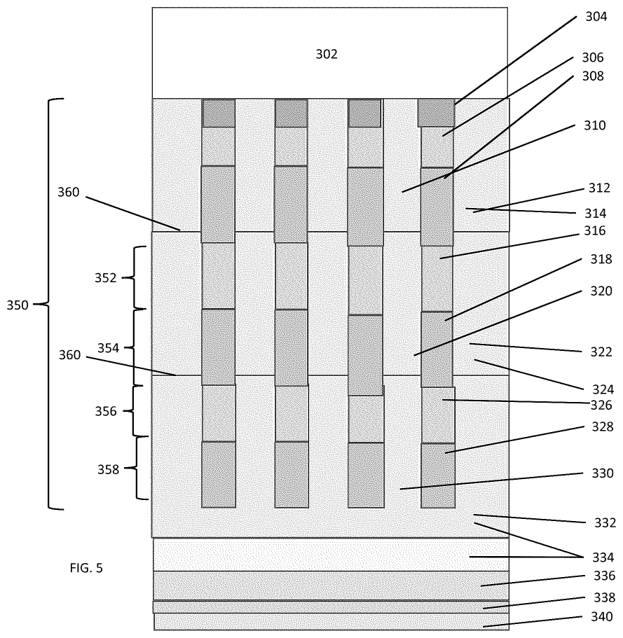

FIG. 5 shows a Superjunction SiC device with composite P-type pillar and low diffusion boron. 302 is Superjunction Schottky diode, PiN diode, or Field Effect Transistor (FET) active structure that injects current into N-type carrier channel. 304 is P-type aluminum high doped concentration 1 blocking junction region of p-type pillar. 306 is P-type aluminum moderate doped concentration 1 region of p-type pillar. 308 is P-type boron moderate doped region of p-type pillar that extends into bottom epitaxial layer to depth of AI implant optionally co-implanted with carbon to reduce carbon vacancies and suppress boron diffusion. 310 is N-type channel region with selected n-type doping concentration to achieve quasi charge balanced on overcompensate lateral boron diffusion. 312 is Optional N-type epitaxial drift layer that has been treated to reduce carbon vacancy less than 1×1015 cm−2. 314 is Upper N-type regrown epitaxial drift layer. 316 is Retrograde P-type aluminum moderate doped region of p-type pillar. 318 is P-type boron moderate doped blocking junction that extends into bottom epitaxial layer to depth of AI implant optionally co-implanted with carbon. 320 is N-type channel region with selected n-type doping concentration to achieve quasi charge balanced on overcompensate lateral boron diffusion. 322 is Optional N-type epitaxial drift layer that has been treated to reduce carbon vacancy less than 1×1015 cm−2. 324 is Bottom N-type epitaxial drift layer 2. 326 is Retrograde P-type aluminum moderate doped region of P-type pillar. 328 is P-type boron moderate doped region of p-type pillar that extends into bottom epitaxial layer to depth of AI implant optionally co-implanted with carbon to reduce carbon vacancies and suppress boron diffusion. 330 is N-type channel region with selected n-type doping concentration to achieve quasi charge balanced on overcompensate lateral boron diffusion. 332 is Optional N-type epitaxial drift layer that has been treated to reduce carbon vacancy less than 1×1015 cm−2. 334 is Bottom N-type epitaxial drift layer. 336 is N-type substrate. 338 is Ohmic metal. 340 is Cathode metal electrode. 350 is Superjunction structure. 352 is 0.1 μm to 20 μm. 354 is 0.1 μm to 40 μm. 356 is 0.1 μm to 20 μm. 358 is 0.1 μm to 40 μm. 360 is Epitaxial regrowth interface.

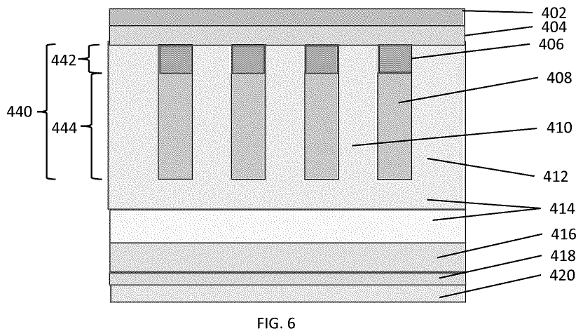

FIG. 6 shows Superjunction SiC Junction Barrier Schottky (JBS) diode with low diffusion boron P-type pillar. 402 is Anode metal electrode. 404 is Schottky metal. 406 is P-type low diffusion boron or aluminum high doped concentration 1 blocking junction region of p-type pillar. 408 is P-type low diffusion boron moderate doped region of p-type pillar optionally co-implanted with carbon to reduce carbon vacancies and suppress boron diffusion. 410 is N-type channel region with selected n-type doping concentration to achieve quasi-charge balanced on overcompensate lateral boron diffusion. 412 is N-type epitaxial drift layer that has been optionally treated to reduce carbon vacancy less than 1×1015 cm−2 to suppress boron diffusion. 414 is N-type epitaxial drift layer. 416 is N-type substrate. 418 is Ohmic metal. 420 is Cathode metal electrode. 440 is Superjunction structure. 442 is 0.1 μm to 0.5 μm. 444 is 0.1 μm to 40 μm.

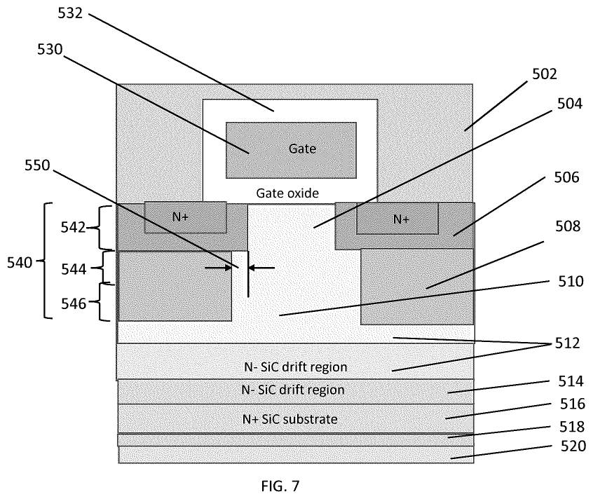

FIG. 7 shows Superjunction SiC DMOSFET with low diffusion boron P-type pillar The low diffusion P-type pillar reduces the electric field in the gate oxide on the bottom of the UMOSFET gate structure. 502 is Source metal electrode. 504 is N-type channel region with selected n-type doping concentration to achieve quasi-charge balanced on overcompensate lateral boron diffusion. 506 is P-type aluminum high doped concentration 1 blocking junction region of P-type pillar. 508 is P-type low diffusion boron moderate doped region of p-type pillar optionally co-implanted with carbon to reduce carbon vacancies and suppress boron diffusion. 510 is N—SiC current spreading layer that has optionally been treated to reduce carbon vacancy less than 1×1015 cm−2 to suppress boron diffusion. 512 is N-type epitaxial drift layer that has been optionally treated to reduce carbon vacancy less than 1×1015 cm−2 to suppress boron diffusion. 514 is N-type epitaxial drift layer. 516 is N-type substrate. 518 is N-type substrate. 520 is Drain metal electrode. 540 is Superjunction structure. 542 is 0.5 μm. 544 is 0.1 μm to 20 μm. 546 is 0.1 μm to 40 μm. 550 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to three microns.

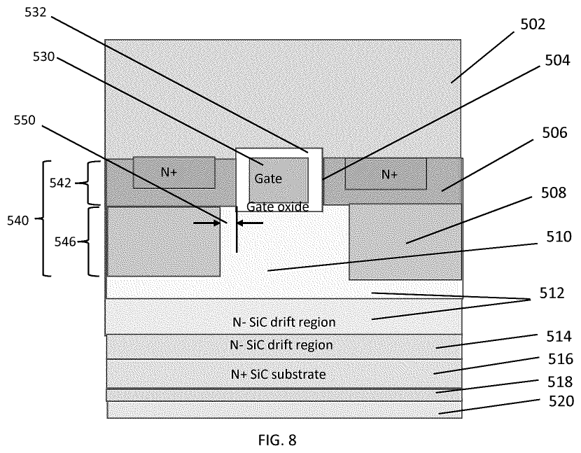

FIG. 8 shows Superjunction SiC UMOSFET with low diffusion boron P-type pillar. The low diffusion P-type pillar reduces the electric field in the gate oxide on the bottom of the UMOSFET gate structure. 502 is Source metal electrode. 504 is N-type channel region with selected n-type doping concentration to achieve quasi-charge balanced on overcompensate lateral boron diffusion. 506 is P-type aluminum high doped concentration 1 blocking junction region of P-type pillar. 508 is P-type low diffusion boron moderate doped region of p-type pillar optionally co-implanted with carbon to reduce carbon vacancies and suppress boron diffusion. 510 is N—SiC current spreading layer that has optionally been treated to reduce carbon vacancy less than 1×1015 cm−2 to suppress boron diffusion. 512 is N-type epitaxial drift layer that has been optionally treated to reduce carbon vacancy less than 1×1015 cm−2 to suppress boron diffusion. 514 is N-type epitaxial drift layer. 516 is N-type substrate. 518 is N-type substrate. 520 is Drain metal electrode. 540 is Superjunction structure. 542 is 0.5 μm. 544 is 0.1 μm to 20 μm. 546 is 0.1 μm to 40 μm. 550 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to 3 microns.

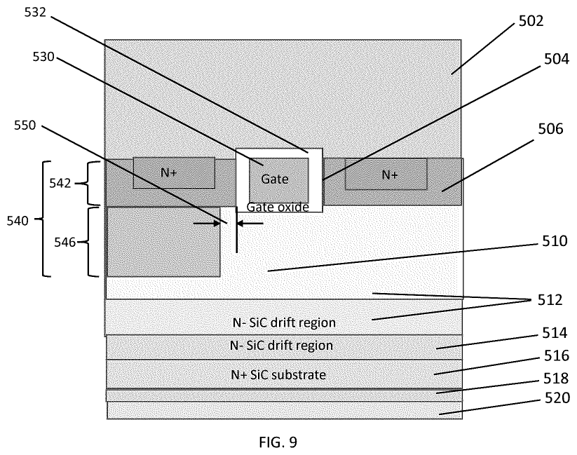

FIG. 9 shows Superjunction SiC CoolMOSFET with low diffusion boron P-type pillar on one side of gate. The low diffusion P-type pillar reduces the electric field in the gate oxide on the bottom of the UMOSFET gate structure. 502 is Source metal electrode. 504 is N-type channel region with selected n-type doping concentration to achieve quasi-charge balanced on overcompensate lateral boron diffusion. 506 is P-type aluminum high doped concentration 1 blocking junction region of P-type pillar. 508 is P-type low diffusion boron moderate doped region of p-type pillar optionally co-implanted with carbon to reduce carbon vacancies and suppress boron diffusion. 510 is N—SiC current spreading layer that has optionally been treated to reduce carbon vacancy less than 1×1015 cm−2 to suppress boron diffusion. 512 is N-type epitaxial drift layer that has been optionally treated to reduce carbon vacancy less than 1×1015 cm−2 to suppress boron diffusion. 514 is N-type epitaxial drift layer. 516 is N-type substrate. 518 is N-type substrate. 520 is Drain metal electrode. 540 is Superjunction structure. 542 is 0.5 μm. 544 is 0.1 μm to 20 μm. 546 is 0.1 μm to 40 μm. 550 is Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to three microns.

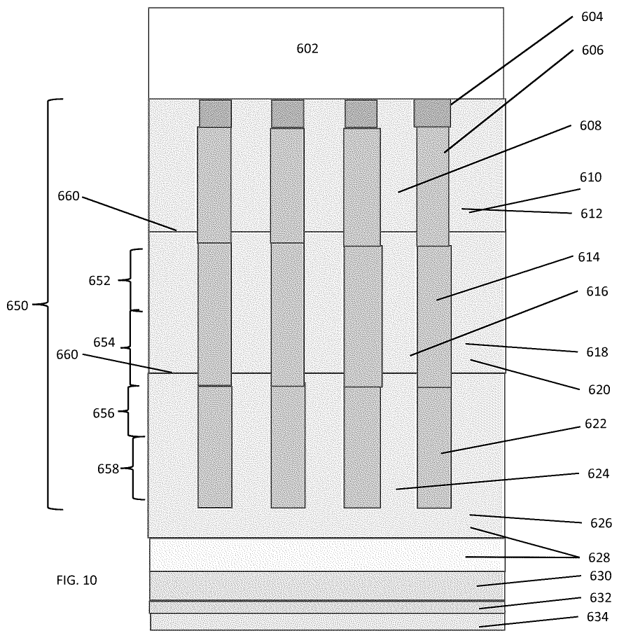

FIG. 10 shows a Superjunction SiC device with low diffusion boron p-type pillar. 602 is Superjunction Schottky diode, PiN diode, or Field Effect Transistor (FET) structure that injects current into N-type carrier channel. 604 is P-type aluminum or low diffusion boron with high doped concentration 1 blocking junction region of p-type pillar. 606 is P-type low diffusion boron moderate doped region of p-type pillar that extends into bottom epitaxial layer to depth of boron retrograde implant optionally co-implanted with carbon to reduce carbon vacancies and suppress boron diffusion. 608 is N-type channel region with selected n-type doping concentration to achieve quasi charge balanced on overcompensate lateral boron diffusion. 610 is Optional N-type epitaxial drift layer that has been treated to reduce carbon vacancy less than 1×1015 cm−2 to suppress boron diffusion. 612 is Upper N-type regrown epitaxial drift layer. 614 shows Retrograde P-type low diffusion boron moderate doped region of p-type pillar that extends into bottom epitaxial layer to depth of boron retrograde implant optionally co-implanted with carbon to reduce carbon vacancies and suppress boron diffusion. 616 shows N-type channel region with selected n-type doping concentration to achieve quasi charge balanced on overcompensate lateral boron diffusion. 618 shows Optional N-type epitaxial drift layer that has been treated to reduce carbon vacancy less than 1×1015 cm−2 to suppress boron diffusion. 620 shows Bottom N-type epitaxial drift layer 2. 622 shows Retrograde P-type low diffusion boron moderate doped region of p-type pillar that extends into bottom epitaxial layer to depth of boron retrograde implant optionally co-implanted with carbon to reduce carbon vacancies and suppress boron diffusion. 624 shows N-type channel region with selected n-type doping concentration to achieve quasi charge balanced on overcompensate lateral boron diffusion. 626 shows Optional N-type epitaxial drift layer that has been treated to reduce carbon vacancy less than 1×1015 cm−2 to suppress boron diffusion. 628 shows Bottom N-type epitaxial drift layer 1. 630 shows N-type substrate. 632 shows Ohmic metal. 634 shows Cathode metal electrode. 650 shows Superjunction structure. 652 shows 0.1 μm to 20 μm. 656 shows 0.1 μm to 20 μm. 658 shows 0.1 μm to 40 μm. 660 shows Epitaxial regrowth interface

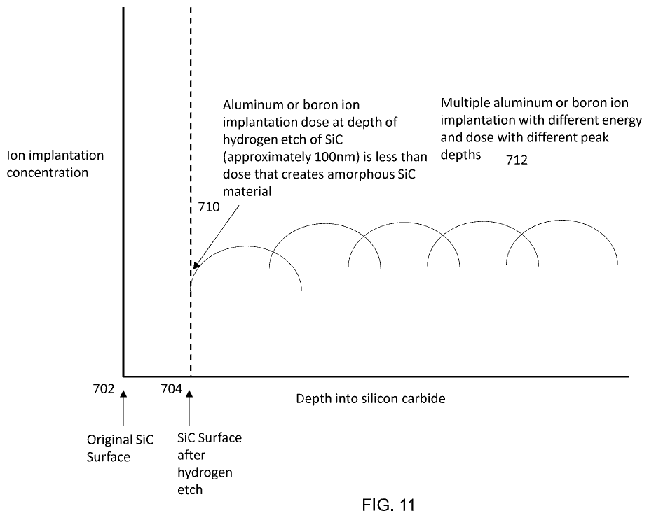

FIG. 11 shows a schematic of a retrograde multi-step ion implant dopant profile. Aluminum or boron retrograde ion implantation to reduce surface defects to enable low defect density SiC epitaxial regrowth layer on a bottom epitaxial layer. It shows a comparison of the depth into silicon carbide and ion implantation concentration. 702 shows the original SiC surface, and 704 shows the SiC surface after hydrogen etching. 710 shows Aluminum or boron ion implantation dose at depth of hydrogen etch of SiC (approximately 100 nm) is less than dose that creates amorphous SiC material. 712 shows Multiple aluminum or boron ion implantation with different energy and dose with different peak depths.

The above-described ion implantation techniques according to embodiments of the present subject disclosure may exhibit a number of advantages. As discussed above, the technique may be used to form p-type pillar junctions, p-wells and other implanted regions that have doping profiles that may result in improved device performance.

Additionally, the use of channeling doping techniques may result in much higher dopant activation levels, such as levels in excess of 95%, which may provide more consistent and/or repeatable doping and which also may reduce the amount of time required for doping since less dopants are required to achieve a given level of activated dopants.

Embodiments of the present subject disclosure have been discussed above with reference to example embodiments in the form of JBS diodes and MOSFETs. However, it will be appreciated that other power semiconductor devices such as, for example, Schottky diodes, PiN diodes, Junction Field Effect Transistors, (JFETs), Bipolar transistors, Insulated Gate Bipolar Transistors, and thyristors.

### Method

Referring to FIG. 2, a second ion implantation mask may be formed on the drift region, and this mask may then be patterned via, for example, photolithography. Referring to FIG. 2, p-type dopants may be implanted into the n-type drift region to form a plurality of p-type composite pillars (only one of which is shown in FIG. 2. The p-type dopants may also be implanted at a predetermined angle with respect to the top surface of the drift region in order to implant the ions in channels that appear at the selected angle in the crystal lattice. For example, the p-type dopant ions can be implanted at the same angle as the optional n-type dopants. The ion implantation technique described above with respect to FIG. 2 may be used to implant the p-type dopant ions in all regions of a wafer that includes the power semiconductor device where p-type dopants are to be implanted in the drift region for forming a superjunction structure. As the p-type dopant ions are implanted at an angle with respect to the top surface of the device, the p-type composite pillar has a pair of slanted sidewalls. The p-type composite pillar may directly contact the n-type pillar.

The second ion implantation mask may then be removed. Via these steps, a semiconductor device is formed that has one or more optional n-type silicon carbide pillars and one or more p-type silicon carbide composite pillars that together form a superjunction structure in the n-type drift region. Referring to FIG. 1, a heavily doped p-type region may be formed in an upper portion of at least the p-type silicon carbide composite pillar in order to form a pillar junction. The pillar junction defines a channel region in an upper portion of the n-type silicon carbide pillar. When the semiconductor device is in its on state, current will flow through the n-type channel region. Contact structures may also be added to the device. As shown in FIG. 1, the contact structures may include, for example, an ohmic contact layer that is on a bottom surface of the substrate, a cathode contact that is on the ohmic contact layer, a Schottky contact layer that is on a top surface of the n-type drift region, and an anode contact that is on the Schottky contact layer.

As shown in FIG. 1, the device includes an n+ substrate, and an n-type drift layer having a doping concentration of about 1.5×1016 cm−3 on the substrate. The drift layer has a thickness of about approximately 5 microns to approximately 100 microns. An n-type current spreading layer having a thickness of about 5 microns and a doping concentration of about 7×1016 cm−3 is on the drift layer. The drift layer and the n-type current spreading layer may together form a drift region of the device.

A p+ well region is formed in the n-type spreading layer, and an n+ source region is formed in the p+ well region. The n+ source region is degeneratively doped to have a doping concentration greater than about 1×1020 cm−3. Likewise, the p-type well has a p+ region at the surface of the p-type well that is degeneratively doped to have a doping concentration greater than about 1×1020 cm−3. An n-type JFET implant region is formed in the n-type current spreading layer adjacent the p+ well region. The n-type JFET region has a doping concentration that is greater than the doping concentration of the n-type current spreading layer. A gate insulating layer is on the n-type current spreading layer, and a gate contact is on the gate insulating layer. A source contact is formed on the n+ source region and contacts the p+ well region. A drain contact is formed on the substrate.

The device further includes a deep ion implanted composite p-type pillar region beneath the p+ well or a deep ion implanted low boron diffusion p-type pillar region beneath the P-type pillar. The deep p-implanted region may have a doping concentration of about 1×1017 cm−3. The deep p-implanted region may extend to a depth of about in the range of 0.1 microns to 100 microns into the drift region. The deep p-type layer may not be so deep, however, as to extend completely through the n-type spreading layer. The deep p-type implanted region may be formed by channeled ion implantation. The deep p-type implanted region may comprise a p-type pillar. The portion of the current spreading layer that is adjacent the deep p-type implanted region may comprise an n-type pillar. The n-type pillar may be formed by ion implantation. These p-type pillars and n-type pillars may form a superjunction structure in the drift region.

Because of this superjunction structure, the top portion of the drift region (i.e., the n-type spreading layer) can be doped more heavily than would otherwise be possible for a conventional structure. This enables the device to have lower on-state resistance than would otherwise be possible for a given pillar voltage.

Next, impurities having a second conductivity type that is opposite the first conductivity type are implanted into selected portions of the drift layer. The drift layer may have a planar upper surface and the impurities may be implanted into selected portions of the planar upper surface of the drift layer using an ion implantation mask. This implantation step may form at least one second conductivity type pillar within the drift layer that is part of a superjunction structure.

The aluminum high doped upper portion of each p-type pillar junction may generate strong electric fields during reverse pillar operation that perform as an electric field shield to shield the Schottky barrier from high electric fields and that may resist high reverse voltages. The aluminum moderate-doped and boron moderate-doped lower portion of each p-type pillar junction may have a doping concentration that is selected to achieve a quasi-charge balance with respect to the n-type channel regions that are interposed therebetween. The device further includes a deep ion implanted composite p-type pillar region beneath the p+ well or a deep ion implanted low boron diffusion p-type pillar region beneath the P-type pillar. The deep p-implanted region may have a doping concentration of about 1×1017 cm−3. The deep p-implanted region may extend to a depth of about in the range of 0.1 microns to 100 microns into the drift region. The lower portions of the channel regions and the lower portions of the aluminum and boron p-type pillar junctions may form a superjunction structure that comprises a series of p-n junctions that exhibit low resistance while still maintaining a high reverse breakdown voltage. By “quasi-charge balanced” it is meant that the charge of the lower aluminum and boron p-type pillar junctions approximately equals the charge of the channel regions. Approximately equal is for example, within 20% of each other—then the lower portions of the aluminum and boron p-type pillar junctions and the channel regions therebetween may act like a superjunction, thereby reducing the conventional tradeoff between on-state resistance and reverse voltage pillar performance,

### Example 1

Presented herein is a non-limiting example of the present subject disclosure, incorporating the teachings and discussions above.

A non-limiting objective of the subject disclosure: to utilize a technique for suppressing boron diffusion for making improved silicon carbide superjunction devices and UMOSFET devices.

Purpose/usefulness of the subject disclosure:
1. aluminum ion implantation is used in silicon carbide devices because the aluminum does not diffuse under high temperature anneal that can close up the current conduction paths
2. Boron typically diffuses significantly and closes up current conduction paths and is not used in SiC devices

Approach: to use carbon implant to reduce carbon vacancies to suppress boron diffusion

Payoff: boron implants that have low boron diffusion will have a large advantage for fabricating SiC Superjunction devices and also for fabricating SiC UMOSFT (beneficial for Large Commercial Markets).

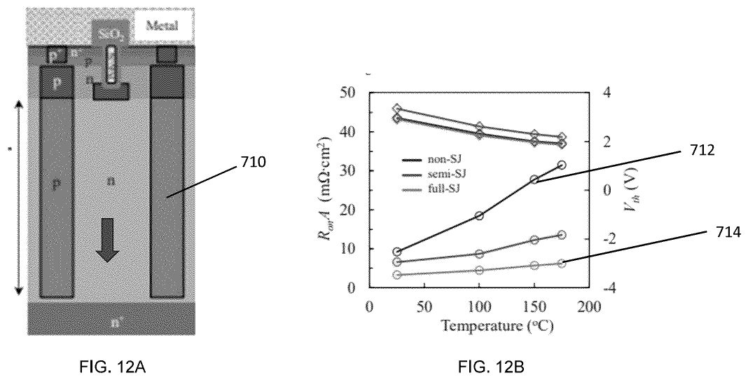

Shown in FIG. 12A is a silicon carbide superjunction power switch. P-type 802 are columns implemented with high energy aluminum ion implantation because aluminum does not diffuse laterally. A conventional boron implant would diffuse laterally and close up the N-type conduction channel.

Since boron has a high diffusivity in silicon carbide, boron diffusion can be suppressed by removal of carbon vacancies in the SiC semiconductor. Ion implantation of carbon creates excess carbon that fill the carbon vacancies.

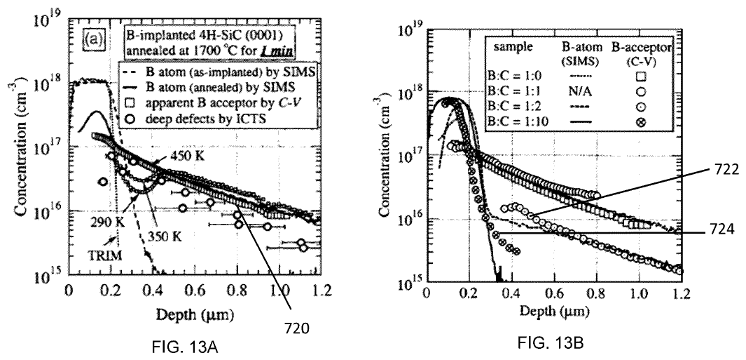

A study by Negero et al. (Y Negero, et. al., “Carrier compensation near tail region in aluminum- or boron-implanted 4H—SiC (0001),” J of App Physic, 2004), is hereby incorporated by reference herein in its entirety into this disclosure. As shown best in FIG. 13A, ion implanted and anneal SiC shows large boron diffusion tail 720 and deep diffusion. As shown in FIG. 13B, co-implantation of carbon and boron shows large reduction in the boron diffusion tail and also can allow complete stoppage of boron diffusion. In the ratio of carbon to boron, there is shown 2:1 reduction in boron diffusion 722. Further, a 10:1 ratio shows complete stoppage of boron diffusion 724. Thus, use of carbon in conjunction with boron allows for reduced boron diffusion.

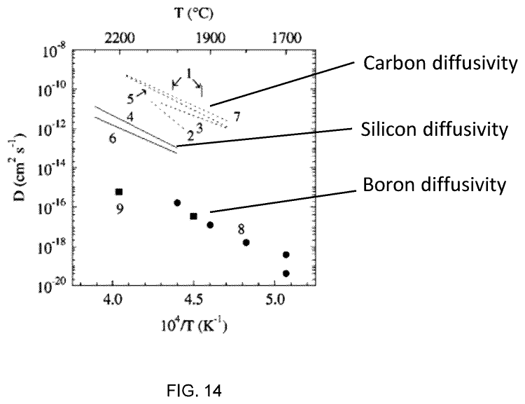

FIG. 14 is part of a study (K. Ruschenscmidt, et. al, “Self-diffusion in isotopically enriched silicon carbide and its correlation with dopant diffusion,” J. of Applied Physics, 2004), that is hereby incorporated by reference herein in its entirety into this disclosure. Carbon has high diffusivity in silicon carbide. Carbon can be co-implanted with boron and diffused. Carbon can be blanket ion implanted and then diffused into the silicon carbide semiconductor.

Referring back to FIG. 12A and considering FIG. 12B, silicon carbide superjunction devices have been fabricated using an aluminum implant. Silicon carbide superjunction devices have lower ON resistance 714 than conventional SiC power switches 712. See, M. Baba, et. al., “Ultra-Low Specific on-Resistance Achieved in 3.3 kV-Class SiC Superjunction MOSFET,” 2021, which is hereby incorporated by reference herein in its entirety into this disclosure.

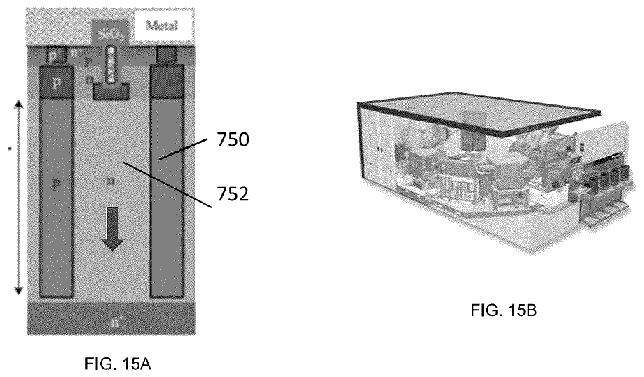

The present subject disclosure expands upon and improves the field of art by utilizing carbon doping through ion implantation to reduce carbon vacancies to suppress lateral boron diffusion in SiC superjunction devices. An advantage of boron ion implant is that boron is a lighter atom and can be ion implanted 2.7× deeper than aluminum ion implants. Boron atomic mass is 10.9 AMU. Aluminum atomic mass is 26.9 AMU. Ratio is 2.74. This implies boron approx. 2.7× deeper. Use channeling to increase ion implantation depth >2 times. FIG. 15A shows a Boron ion implanted region 750. Utilize carbon+boron ion implantation or unmasked carbon ion implantation to reduce carbon vacancies to reduce lateral diffusion of boron into the N-type conduction channel 752. FIG. 15B shows that Commercial High Energy Ion Implanters are available from Axcelis up to 15 MeV. (See Baba et al., cited above.)

### Example 2

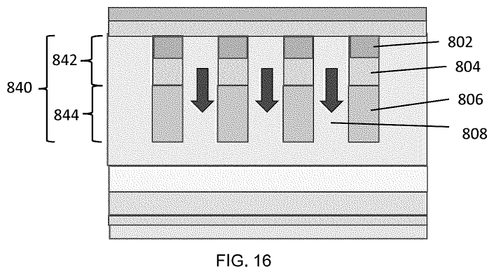

Another exemplary embodiment of present subject disclosure results in a Composite pillar structure of aluminum and boron, as shown in FIG. 16. The aluminum dopant has a lower ionization energy and thus higher conductivity. 802 shows P-type aluminum high doped concentration 1 blocking junction. 804 shows P-type aluminum moderate doped concentration Higher activation, lower resistivity. 806 shows P-type boron doped region of p-type pillar. 808 shows N-type epitaxial drift layer that has been treated to reduce carbon vacancy less than 1×1015 cm−2 to suppress boron diffusion. 840 shows Superjunction structure. 842 shows 0.2 μm to 20 μm. 844 shows 0.1 μm to 40 μm.

### Example 3

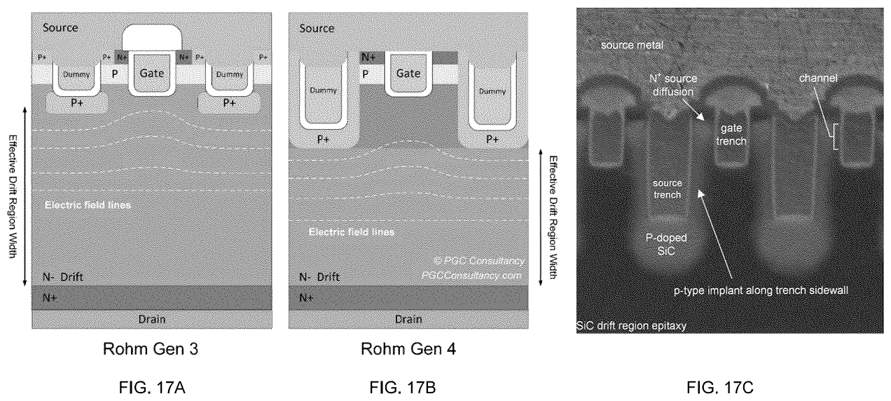

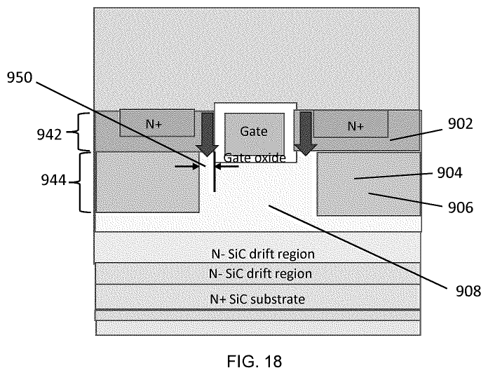

Another exemplary embodiment is shown in FIGS. 17-18. Briefly, FIGS. 17A, 17B, and 17C show state of the art for Rohm UMOSFET. The structure has dummy trench structures on the sides of UMOSFET to reduce electric field at the bottom of the trench. See https://www.techinsights.com/blog/rohm-gen-4-technical-review, which is incorporated by reference herein in its entirety into this disclosure.

FIG. 18 shows a Device structure with low carbon vacancies and ion implanted boron for commercial SiC DMOSFET. This allows higher cell density (conventional Rohm structure has dummy trench structures on the sides of UMOSFET to reduce electric field at the bottom of the trench). It also allows lower ion implant energy. 902 is P-type aluminum high doped concentration 1 blocking junction. 904 is P-type boron doped region. 906 shows P-well reduces the electric field on bottom of gate oxide for improved reliability. 908 shows N-type epitaxial drift layer that has been treated to reduce carbon vacancy less than 1×1015 cm−2 to suppress boron diffusion. 942 shows 0.5 μm. 944 shows 0.1 μm to 4 μm. 950 shows Offset of P-type pillar from edge of P-well blocking junction. The edge of the diffusion p-type pillar near the n-type JFET region may be coincident with the edge of the p-type well near the n-type JFET region or may be offset from the edge of the p-well by a lateral separation in the range of zero microns to 3 microns.

### Applications

There are limitless applications of the concepts presented herein. For example, defense and security applications may include, but not be limited to: compact and efficient power systems for ship, UAV, USV, UUV, space, and radar. Ultra-wide bandgap semiconductors offer low-cost power switching and >1000× performance improvement. The primary need for very high voltage power electronic components for high density ship electrical power conversion and distribution. Commercial interest/applications includes but are not limited to electric power conversion and control components for automobiles, railways, and especially for electric power grids (smart grid, distributed generation/storage and control).

### Concluding Remarks

Although the present subject disclosure has been described in connection with preferred embodiments thereof, it will be appreciated by those skilled in the art that additions, deletions, modifications, and substitutions not specifically described may be made without departing from the spirit and scope of the subject disclosure. Terminology used herein should not be construed as being “means-plus-function” language unless the term “means” is expressly used in association therewith.

The foregoing disclosure of the exemplary embodiments of the present subject disclosure has been presented for purposes of illustration and description. It is not intended to be exhaustive or to limit the subject disclosure to the precise forms disclosed. Many variations and modifications of the embodiments described herein will be apparent to one of ordinary skill in the art in light of the above disclosure. The scope of the subject disclosure is to be defined only by the claims appended hereto, and by their equivalents.

Further, in describing representative embodiments of the present subject disclosure, the specification may have presented the method and/or process of the present subject disclosure as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present subject disclosure should not be limited to the performance of their steps in the order written, and one skilled in the art can readily appreciate that the sequences may be varied and still remain within the spirit and scope of the present subject disclosure.

All documents mentioned herein are hereby incorporated by reference for the purpose of disclosing and describing the particular materials and methodologies for which the document was cited.

What is claimed is:

1. A semiconductor device, comprising:
a drift region having an upper portion and a lower portion with a first conductivity type in the lower portion; and
a plurality of implanted regions containing boron and having a second conductivity type in the upper portion of the drift region, wherein the low boron diffusion is formed so that the boron diffusion in the implanted regions is limited;
wherein the lower portion of the implanted regions form a superjunction structure in the drift region.

2. The semiconductor device of claim 1, wherein the low diffusion boron with limited boron diffusion occurs through reduction of carbon vacancies in a silicon carbide epitaxial layer.

3. The semiconductor device of claim 1, wherein the low diffusion boron with limited boron diffusion occurs through rapid thermal annealing to minimize lateral diffusion.

4. The semiconductor device of claim 1, wherein the low diffusion boron with limited boron diffusion occurs through using low temperature epitaxial growth.

5. The semiconductor device of claim 4, wherein low temperature epitaxial growth is at or below 13000.

6. The semiconductor device of claim 1, wherein the first conductivity type comprises n-type.

7. The semiconductor device of claim 1, wherein the implanted regions comprise P-type.

8. The semiconductor device of claim 7, wherein the P-type comprise composite P-type.

9. The semiconductor device of claim 1, wherein the implanted region has an upper portion and a lower portion.

10. The semiconductor device of claim 9, wherein the composite P-type upper portion comprises a first doping type having a first concentration.

11. The semiconductor device of claim 10, wherein the composite P-type lower portion comprises a second doping type having a second concentration.

12. The semiconductor device of claim 11, where the first doping type comprises aluminum and the second doping type comprises boron.

13. The semiconductor device of claim 11, wherein the P-type low diffusion boron is positioned beneath at least P-type well, wherein the low diffusion boron p-type implanted region reduces an electric field in an insulator beneath a gate electrode.

14. The semiconductor device of claim 13, wherein the first conductivity type comprises n-type.

15. The semiconductor device of claim 14, wherein the implanted regions comprise P-type.

16. The semiconductor device of claim 15, wherein the P-type comprise boron.

17. The semiconductor device of claim 16, wherein the P-type boron is positioned beneath a P-type well, and wherein the P-type boron implanted region is formed using channeling ion implantation.

18. The semiconductor device of claim 13, wherein the implanted regions have an upper portion and a lower portion.

19. The semiconductor device of claim 1, wherein the lower portion of the implanted regions are quasi-charge balanced with adjacent portions of the drift region.

20. A semiconductor device comprising:
a drift region having a first n-type conductivity, type; and
a plurality of boron P-type implanted regions having a P-type conductivity type in an upper portion of the drift region,
wherein the first n-type conductivity type dopant density overcompensates boron dopant that diffuses into the first n-type conductivity type; and
wherein the lower portions of the implanted regions form a superjunction structure in the drift region.
